(19) United States
(12) Patent Application Publication
(10) Pub. No.: US 2024/0043460 A1
(43) Pub. Date: Feb. 8, 2024

(54) PHOSPHORESCENT C^C* PLATINUM(II) COMPLEXES WITH BORONIC LIGANDS AND THEIR USE AS EMITTERS IN OLEDS

(71) Applicant: TECHNISCHE UNIVERSITÄT DRESDEN, Dresden (DE)

(72) Inventors: Thomas STRAßNER, Dresden (DE); Johannes SÖLLNER, Dresden (DE)

(21) Appl. No.: 17/433,005

(22) PCT Filed: Feb. 21, 2020
(86) PCT No.: PCT/EP2020/054656

§ 371 Date: Aug. 23, 2021

(30) Foreign Application Priority Data
Feb. 22, 2019 (DE) 10 2019 104 567.3

(51) Int. Cl. C07F 15/00; C09K 11/06; H10K 85/30; H10K 85/60

(52) U.S. Cl. CPC C07F 15/0086; C09K 11/06; H10K 85/346; H10K 85/322; H10K 85/654; H10K 85/658; C09K 2211/185

(57) ABSTRACT

The invention relates to novel platinum(II) complexes with C\hat{ }C* and borate ligands of the following formula (I), processes for their preparation and their use in OLEDs.

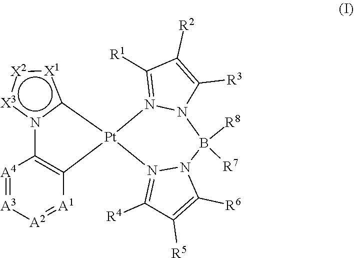

The present invention relates to tetracoordinated heteroleptic C\hat{ }C* platinum(II) complexes with bis(pyrazolyl)borate ligands, methods for their preparation and their use in organic light-emitting diodes (OLEDs).

In OLEDs, the property of materials to emit light is exploited when these materials are excited by electric current. In particular, OLEDs are of interest as an alternative to cathode ray tubes and liquid crystal displays for the production of flat panel displays. Due to the very compact design and intrinsically low power consumption, the device containing OLEDs is particularly suitable for mobile applications, e.g. applications in cell phones, laptops, etc., as well as for lighting.

The prior art discloses a variety of materials that emit light when excited, including quadruply coordinated heteroleptic platinum(II) complexes with bis(pyrazolyl)borate ligands. From Niedermair et al, Inorganica Chimica Acta 360 (2007) 2767-2777 (doi:10.1016/j.ica.2007.02.001), some heteroleptic κ2(N,C²)-2-phenylpyridine platinum complexes with bis(pyrazolyl)borate ligands are known to have emission maxima between 488 and 551 nm and melting points between 149 and 213° C. Ma et al, J Am Chem Soc 2005, 127, 28-29 describe photophysical properties of dinuclear platinum complexes with C\hat{ }N ligands and bridging p-pyrazolate ligands and a mononuclear platinum complex with a C\hat{ }N ligand and a bis(pyrazolyl)borate ligand. The dinuclear complexes are highlighted as potential emitters. Saito et al, Inorg. Chem. 2008, 47, 43289-4337 analyze the possible transitions between different molecular orbitals in the aforementioned dinuclear complexes. Berenguer et al, Organometallics 2011, 30, 5776-5792 describe heteroleptic (C\hat{ }N)-platinum complexes (C\hat{ }N=benzoquinolate, 2-phenylpyridinate, and 2-phenylquinolate) with bis(pyrazolyl)borate ligands. From Salazar et al, Organometallics 2006, 25, 172-176 and Padilla et al, Dalton Trans. 2016, 45, 16878, iridium complexes with hydrotris(3,5-dimethylpyrazolylborate) ligands are also known. WO 2012/098996 A¹ describes heteroleptic iridium complexes with C\hat{ }C* ligand and bis(pyrazolyl)borate ligand, and further a heteroleptic platinum(II) complex with N\hat{ }C* ligand and bis(pyrazolyl)borate ligand. Independently, tetracoordinated heteroleptic platinum(II) complexes with C\hat{ }C* ligands are known, cf. Tronnier et al, J. Mater. Chem. C, 2015, 3, 1680; WO 2014/024131 A¹; WO 2014/177518 A1.

The suitability of platinum(II) complexes as emitters results from the special electronic properties of these compounds, as they are diamagnetic low-spin complexes suitable for so-called triplet harvesting. This means that excitation of corresponding molecules can lead to a comparatively high yield of radiation in certain wavelength ranges, which can make them particularly suitable for applications in OLEDs. However, further representatives of corresponding compounds are needed. In particular, there is high interest in corresponding complexes that phosphoresce with wavelengths in the short-wavelength range of the visible spectrum.

Irrespective of this, the stability of OLEDs and devices containing emitters must be improved. In particular, corresponding devices should become more durable. Red, yellow and blue OLEDs are required for the production of RGB OLED displays. Disadvantages of the present OLED technology result from the short lifetime of compounds phosphorescing especially in the short wavelength (blue) region, i.e. blue, compared to molecules phosphorescing in the middle (green) and longer wavelength (red) region of the visible spectrum. Disadvantages resulting from the short-lived nature of known blue phosphorescent compounds are avoided in the prior art by using bypass solutions to represent the color blue in OLED applications, for example by using filters, which in turn can result in other disadvantages, such as an increased space requirement of a pixel, and/or a more complex structure of an OLED device.

Substances suitable as emitters should therefore not only emit radiation in the shortest possible wavelength range of visible light, but also be as thermally stable as possible.

Accordingly, it is the task of the invention to provide heteroleptic platinum(II) complexes with bis(pyrazolyl)borate ligands which are suitable for use in OLEDs, in particular as emitters or as light-emitting substances, and which at the same time make it possible to provide emitters which phosphoresce in the short-wave region of the spectrum, if possible, and which also have good thermal stability.

The above problem is solved by heteroleptic C\hat{ }C* platinum(II) complexes with bis(pyrazolyl)borate ligands of the following formula (I).

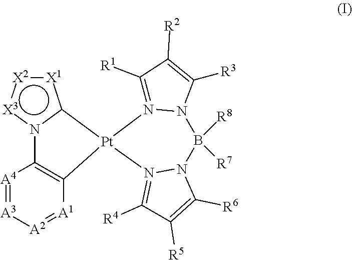

where
(a) A¹ to A⁴ denote: A¹N or CR^{A1}, A² N or CR^{A2}, A³ N or CR^{A3}, A⁴ N or CR^{A4}, and
(b) X¹ to X³ mean:
   (i) X¹ NR⁹, X² CR¹⁰, and X³ CR¹¹, or
   (ii) X¹ CR¹², X² NR¹³, and X³ CR¹⁴, or
   (iii) X¹ NR¹⁵, X² N, and X³ CR⁶, or
   (iv) X¹ NR¹⁷, X² CR⁸, and X³ N, or
   (v) X¹ CR¹⁹, X² NR²⁰, and X³ N, or
   (vi) X¹ S, X² CR²¹ and X³ CR²², and
(c) R^{A1} to R^{A4} and R¹ to R²² are each independently H, with the proviso that R⁹, R¹³, R¹⁵, R¹⁷, R²⁰ are each not H: H, a halogen atom, donor substituent, acceptor substituent, linear or branched, substituted or unsubstituted alkyl group having 1 to 20, preferably 1 to 9, more preferably 1 to 4 carbon atoms, in which optionally at least one carbon atom is replaced by a heteroatom, substituted or unsubstituted cycloalkyl group having 3 to 20, preferably 3 to 9, more preferably 5 to 6 carbon atoms, in which optionally at least one carbon atom is replaced by a heteroatom, substituted or unsubstituted aryl radical having 6 to 30, preferably 6 to 18 carbon atoms, substituted or unsubstituted heteroaryl radical having 5 to 30, preferably 5 to 18 carbon and/or hetero atoms, or two or more of the following radicals, together with the atoms to which they are bonded, form one or more rings and/or one or more fused aromatic ring systems having in each case 5 to 30, preferably 5 to 18 carbon and/or hetero atoms, which are in each case substituted or unsubstituted:
R^{A1} to R^{A4} and/or, when X³ is CR¹¹: R⁹ to R¹¹; when X³ is CR¹⁴: R¹² to R¹⁴; when X³ is CR¹⁶: R¹⁵, R¹⁶: when X³ is N and X¹ is NR¹⁷: R¹⁷, R¹⁸; when X³ is N and X¹ is CR¹⁹: R¹⁹, R²⁰; or when X³ is CR²²: R²¹, R²²; and/or two or more of the radicals from the respective radical group R¹ to R³, R⁴ to R⁶ and/or R⁷ and R⁸ form, within the radical group, in each case together with the atoms to which they are bonded, a ring or a fused aromatic ring system having 5 to 30, preferably 5 to 18, carbon and/or heteroatoms, the ring or the fused aromatic ring system being substituted or unsubstituted.

The radicals R¹ to R⁸ located on the bis(pyrazolyl)borate ligand each preferably mean: H, halogen atom, donor substituent, acceptor substituent, linear or branched, substituted or unsubstituted alkyl radical having 1 to 4 carbon atoms, substituted or unsubstituted aryl radical having 6 to 30, preferably 6 to 18, even more preferably 6 carbon atoms, substituted or unsubstituted heteroaryl radical having 5 to 30, preferably 5 to 18 carbon and/or hetero atoms, or two or more of the radicals from the respective radical group R¹ to R³, R⁴ to R⁶ and/or R⁷ and R⁸ form within the radical group in each case together with the atoms to which they are bonded a ring or a fused aromatic ring system having 5 to 18 carbon and/or hetero atoms, the ring or the fused aromatic ring system being substituted or unsubstituted.

A¹ means N or CR^{A1}, preferably CR^{A1}. A² means N or CR^{A2}, preferably CR^{A2}. A³ means N or CR^{A3}, preferably CR^{A3}. A⁴ means N or CR^{A4}, preferably CR^{A4}.

The radicals R^{A1} to R^{A4} and R⁹ to R²² located on the C\hat{ }C* ligand are each preferably independently of one another, with the proviso that R⁹, R¹³, R¹⁵, R¹⁷, R²⁰ are each not H: H, a halogen atom, donor substituent, acceptor substituent, linear or branched, substituted or unsubstituted alkyl radical having 1 to 9, more preferably 1 to 4 carbon atoms, in which optionally at least one carbon atom is replaced by a heteroatom, substituted or unsubstituted cycloalkyl radical having 3 to 9, more preferably 5 to 6 carbon atoms, in which optionally at least one carbon atom is replaced by a heteroatom, substituted or unsubstituted aryl radical having from 6 to 18, preferably 6, carbon atoms, substituted or unsubstituted heteroaryl radical having from 5 to 18 carbon and/or hetero atoms, or two or more of the following radicals, together with the atoms to which they are attached, form one or more rings and/or one or more fused aromatic ring systems, each having from 5 to 18 carbon and/or hetero atoms, each of which is substituted or unsubstituted R^{A1} to R^{A4} and/or, when X³ is CR¹¹: R⁹ to R¹¹; when X³ is CR¹⁴: R¹² to R¹⁴; when X³ is CR¹⁶: R¹⁵, R¹⁶; when X³ is N and X¹ is NR¹⁷: R¹⁷, R¹⁸; when X³ is N and X¹ is CR¹⁹: R¹⁹, R²⁰; or when X³ is CR²²: R²¹, R²².

Acceptor and/or donor substituents are preferably selected from the group comprising halogen radicals, including preferably —F, —Cl, —Br, —I, more preferably —F, —Cl, —Br, particularly preferably —F, alkoxy radicals, carbonyl radicals (—C(O)R), amine radicals (—NH₂, —NHR, —NR₂), amide radicals, CF₃ groups, CN groups, NC groups, SCN groups, the nitro or NO₂ group, bordiorganyl groups —BR₂, where R in each case represents any organic radical.
X¹ to X³ preferably mean:
   (i) X¹ NR⁹, X² CR¹⁰, and X³ CR¹¹, or
   (ii) X¹ CR¹², X² NR¹³, and X³ CR¹⁴, or
   (iii) X¹ NR¹⁵, X² N, and X³ CR¹⁶, or (
   (iv) X¹ NR¹⁷, X² CR¹⁸, and X³ N, or
   (v) X¹ CR¹⁹, X² NR²⁰, and X³ N.

R^{A1} to R^{A4} independently of one another in each case particularly preferably denote H, halogen or methyl, donor or acceptor substituent, or R^{A2} and R^{A3} or R^{A3} and R^{A4} together with the atoms to which they are bonded form a fused aromatic ring system having 5 to 18 carbon and/or hetero atoms, the fused aromatic ring system being substituted or unsubstituted.
X¹ to X³ mean particularly preferably:
   (i) X¹ NR⁹, X² CR¹⁰, and X³ CR¹¹,
   (iii) X¹ NR¹⁵, X² N, and X³ CR¹⁶,
   (iv) X¹ NR¹⁷, X² CR¹⁸, and X³ N, or
   (v) X¹ CR¹⁹, X² NR²⁰, and X³ N.
X¹ to X³ most preferably mean:
   (i) X¹ NR⁹, X² CR¹⁰, and X³ CR¹¹,
   (iv) X¹ NR¹⁷, X² CR¹⁸, and X³ N, or
   (v) X¹ CR¹⁹, X² NR²⁰, and X³ N.

Platinum(II) complexes according to the invention can be prepared by processes comprising contacting platinum compounds suitable for this purpose, preferably selected from the group comprising Pt(COD)Cl₂ (COD=cycloocta-1,5-diene), Pt(PPh₃)₂Cl₂, Pt(pyridine)₂Cl₂, Pt(NH₃)₂Cl₂, Pt(acac)₂, PtCl₂, K₂PtCl₄, particularly preferably Pt(COD)Cl₂, with a C\hat{ }C* ligand or a C\hat{ }C* ligand precursor, preferably of the following formula (II),

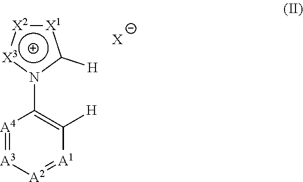

wherein X¹ to X³ and A¹ to A⁴ have the same meanings as described above in connection with formula (I), and X is an anion such as a halide ion, preferably Cl⁻, Br⁻, I⁻, particularly preferably I⁻, or an anion selected from the group comprising BF₄⁻, PF₆⁻, N(SO₂CF₃)₂⁻, SbF₆⁻, ClO₄⁻, ½ SO₄²⁻, preferably BF₄⁻ or PF₆⁻, particularly preferably BF₄⁻, and a bis(pyrazolyl)borate ligand.

Platinum(II) complexes according to the invention can be used in an OLED.

In the context of the present invention, terms such as aryl radical, heteroaryl radical, fused aromatic ring system, alkyl radical, “substituted” and others have the following meanings:

Aryl radical: An aryl radical or group is a radical with a backbone of 6 to 30 carbon atoms, preferably 6 to 18 carbon atoms, which is built up from an aromatic ring or several fused aromatic rings. Suitable backbones are, for example, phenyl, naphthyl, anthracenyl or phenanthrenyl. This backbone may be unsubstituted, i.e., all carbon atoms that are substitutable bear hydrogen atoms, or substituted at one, more or all substitutable positions of the backbone. Preferably, the aryl radical or group is a C₆ aryl radical optionally substituted with at least one of the substituents listed below.

“Substituted”: substituted means that one or more hydrogen atoms are replaced by other substituents. Suitable substituents are, for example, alkyl radicals, preferably alkyl radicals having 1 to 8 carbon atoms, particularly preferably methyl, ethyl, iso-propyl or t-butyl, aryl radicals, preferably C₆ aryl radicals, which in turn may be substituted or unsubstituted, heteroaryl radicals, preferably heteroaryl radicals, which contain at least one nitrogen atom, particularly preferably pyridyl radicals, alkenyl radicals, preferably alkenyl radicals, which carry only one double bond, particularly preferably alkenyl radicals having only one double bond and 1 to 8 carbon atoms, or (functional) groups having donor or acceptor effect or properties. Groups having donor or acceptor effect or properties are also referred to herein as donor or acceptor substituents.

(Functional) groups with donor or acceptor effect or properties: Groups with donor effect or properties or donor substituents are groups that donate electron density to the molecule to which they are connected. Groups with donor effect unfold an electron push by a positive inductive (+I) and/or positive mesomeric (+M) effect. Groups with acceptor effect or acceptor substituents are groups that exhibit a negative inductive (−I) and/or negative mesomeric (−M) effect. Suitable groups with donor or acceptor effect are halogen radicals, preferably F, Cl, Br, I particularly preferably F, alkoxy radicals, aryloxy radicals, carbonyl radicals (—C(O)R), ester radicals (—COOR), amine radicals (—NH₂, —NHR, —NR₂), amide radicals, CH₂F groups, CHF₂ groups, CF₃ groups, CN groups, NC groups, thio groups, SCN groups, NCS groups, the nitro or NO₂ group, bordiorganyl groups —BR₂, and diorganylphosphane groups —PR₂, where R is in each case any organic radical selected, for example, from the group comprising alkyl radicals, preferably alkyl radicals having 1 to 9 carbon atoms, particularly preferably methyl, ethyl, iso-propyl or t-butyl, aryl radicals, preferably C₆ aryl radicals, which in turn may be substituted or unsubstituted, heteroaryl radicals, preferably heteroaryl radicals which contain at least one nitrogen atom, particularly preferably pyridyl radicals, alkenyl radicals, preferably alkenyl radicals which carry only one double bond, particularly preferably alkenyl radicals having only one double bond and 1 to 8 carbon atoms.

Heteroaryl radical: A heteroaryl radical or heteroaryl group is a radical containing 5 to 30, preferably 5 to 18, carbon and/or hetero atoms. Preferred heteroatoms are N, O, and S. Most preferably, a heteroaryl radical contains one or two heteroatoms. In particular, the backbone of the heteroaryl radical is selected from pyridyl, pyrimidyl, pyrazyl, triazyl, and five-membered heteroaromatics such as pyrrole, furan, thiophene, pyrazole, imidazole, triazole, oxazole, thiazole. The backbone may be substituted at none, one, more or all substitutable positions of the backbone.

Fused aromatic ring system: A fused aromatic ring system is a ring system with a backbone of 6 to 30 carbon atoms or 5 to 30 carbon and/or heteroatoms, preferably 6 to 18 carbon atoms or 5 to 18 carbon and/or heteroatoms, which is built up from one aromatic ring or several fused aromatic rings. Suitable backbones include benzofuryl, phenyl, naphthyl, anthracenyl, or phenanthrenyl, to name a few. This backbone may be unsubstituted, i.e., all carbon atoms, and optionally heteroatoms, that are substitutable bear hydrogen atoms, or substituted at one, more or all substitutable positions of the backbone.

Alkyl radical: An alkyl radical or alkyl group is a radical with 1 to 20 carbon atoms, preferably 1 to 9 carbon atoms, particularly preferably 1 to 4 carbon atoms. This alkyl radical may be branched or unbranched and optionally interrupted with one or more heteroatoms, preferably N, O or S. Furthermore, this alkyl radical may be substituted with one or more substituents mentioned above in connection with the aryl groups. The alkyl radical may also bear one or more aryl groups. In this regard, all of the aryl groups listed above are suitable. Examples of preferred alkyl radicals are alkyl radicals selected from the group consisting of methyl, ethyl, iso-propyl, n-propyl, iso-butyl, n-butyl, t-butyl, sec-butyl, iso-pentyl, n-pentyl, sec-pentyl, neo-pentyl, n-hexyl, hexyl and sec-hexyl. Examples of particularly preferred alkyl radicals are methyl, iso-propyl, tert-butyl, especially methyl.

Cycloalkyl radical: A cycloalkyl radical or cycloalkyl group is a mono-, di- or tricyclic radical having 3 to 20 carbon atoms, preferably 3 to 9 carbon atoms, particularly preferably 5 to 6 carbon atoms. This cycloalkyl radical may optionally be interrupted by one or more heteroatoms, preferably N, O or S. The cycloalkyl radical may be unsubstituted or substituted, i.e. substituted with one or more of the substituents mentioned with respect to the aryl groups. It is also possible for the cycloalkyl radical to carry one or more aryl or heteroaryl groups. All of the aryl or heteroaryl groups listed above are suitable.

Ring: When it is described herein that two or more radicals together with the atoms to which they are attached form a ring having from 5 to 30 carbon and/or heteroatoms, each of which is substituted or unsubstituted, this includes wholly or partially saturated as well as unsaturated rings.

Complexes According to the Invention of Formula (I)

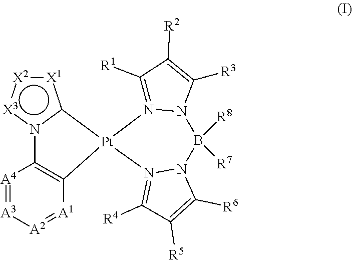

have two bidentate ligands. The ligand with groups A¹ to A⁴ and X¹ to X³ is also referred to herein as the “C\hat{ }C* ligand”. This designation is intended to clarify that the ligand binds to the central atom on the one hand with a formally negatively charged carbon atom (“C” in “C\hat{ }C* ligand”), and on the other hand with a carbene carbon atom (“C*” in “C\hat{ }C* ligand”), both carbon atoms being connected to each other via further intervening atoms (“^{A}” in “C\hat{ }C* ligand”). Together with the central atom, the C\hat{ }C* ligand forms the five-membered metallacycle recognizable in formula (I), comprising N.

Groups X¹ to X³ on the C\hat{ }C* ligand may be selected to form, together with the N atom and the carbene carbon atom coordinating to the central atom, (i) an imidazole ring (i) classically ((NHC) ligand) or (ii) non-classically ((aNHC) ligand) bonded to the central atom, (iii) form a 4H-1,2,4-triazole ring having a 5-ylidene group, (iv) form a 1H-1,2,4-triazole ring having a 5-ylidene group, (v) form a 1,2,3-triazole ring, (vi) form a thiazole ring having a 2-ylidene group.

For a better understanding, alternatives (i)-(vi) are illustrated in the following Table 1. Shown therein in each case is the N-heterocyclic five-membered ring of formula (I) now carrying specific groups X¹ to X³ in accordance with the above alternatives. Bonds which are part of the five-membered metallacycle comprising platinum recognizable in formula (I) are interrupted therein by serpentine lines.

TABLE 1
Alternatives (b)(i)-(vi)

| | |
|---|---|
| 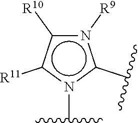 | (i) |
| Imidazole ring as part of a | |
| classical NHC ligand | |
| 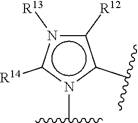 | (ii) |
| Imidazole ring as part of an | |
| aNHC ligand | |
| 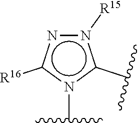 | (iii) |
| 4H-1,2,4-triazole ring | |
| with 5-ylidene group | |
| 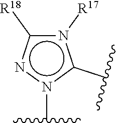 | (iv) |
| 1H-1,2,4-triazole ring | |
| with 5-ylidene group | |
| 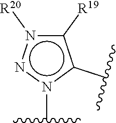 | (v) |
| 1,2,3-triazole ring | |
| 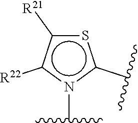 | (vi) |
| Thiazole ring | |
| with 2-ylidene group | |

As readily apparent from Table 1, in the complexes of the invention, the carbene carbon atom of the C\hat{ }C* ligand forming a bond to platinum is a ring atom of an imidazole, triazole or thiazole ring, such that the carbene carbon atom is adjacent to each of a nitrogen atom and a nitrogen atom, a nitrogen atom and a carbon atom, or a nitrogen atom and a sulfur atom.

The carbene carbon atom bonding towards the metal atom is also called the ylidene carbon atom or ylidene group. This carbon atom is essentially sp² hybridized and is part of a conjugated n-electron system. The conjugated π-electrons are each represented herein either with a double bond symbolizing 2 π-electrons and a pitch circle symbolizing 4 π-electrons, or with a circle symbolizing 6 π-electrons. In the following, both types of representation are shown by means of two concrete compounds.

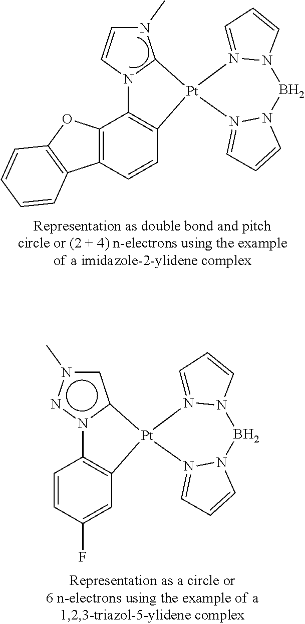

Two or more of R^{A} through R^{A4} and/or, if X³ is CR¹¹: R⁹ through R¹¹; if X³ is CR¹⁴: R¹² through R¹⁴; if X³ is CR¹⁶: R¹⁵, R¹⁶: if X³ is N and X¹ is NR¹⁷: R¹⁷, R¹⁸; if X³ is N and X¹ is CR¹⁹: R¹⁹, R²⁰; or if X³ is CR²²: R²¹, R²²; together with the atoms to which they are attached, may form one or more rings and/or one or more fused aromatic ring systems containing from 5 to 18 carbon and/or heteroatoms, each substituted or unsubstituted, so that the C\hat{ }C* ligand of the Pt(II) complex according to the invention comprises, for example, a benzofuryl, benzothiophenyl, dibenzofuryl, dibenzothiophenyl, naphthyl, anthracenyl, phenanthrenyl, fluorenyl or also a carbazole group or imidazopyridine group, which is optionally substituted. On the C\hat{ }C* ligand, a corresponding ring or ring system may be formed either on the five-membered ring of the ligand, on the six-membered ring of the ligand, or on both rings simultaneously, and/or connecting the two rings. The latter would be the case, for example, if the radicals R^{A4} and, if X³ is CR¹¹: R¹¹; if X³ is CR¹⁴: R¹⁴; if X³ is CR¹⁶: R¹⁶; if X³ is CR²²: R²² as defined above together with the atoms to which they are attached form a ring or a fused aromatic ring system.

In addition, two or more of the radicals from the respective radical group R¹ to R³, R⁴ to R⁶, and/or R⁷ and R⁸ within the radical group may each, together with the atoms to which they are attached, form a ring or fused aromatic ring system having 5 to 18 carbon and/or heteroatoms, the ring or fused aromatic ring system being substituted or unsubstituted. For example, the borate ligand may have a cycloocta-1,5-diyl group, and/or the pyrazole rings may be part of a fused aromatic ring system.

Surprisingly, compounds according to the invention exhibit clear luminescence in the blue region of the visible spectrum with comparatively good thermal stability. Complexes according to the invention are therefore particularly suitable as emitter molecules in OLEDs. In particular, the present invention enables to provide complexes exhibiting electroluminescence especially in the blue region of the electromagnetic spectrum. The complexes according to the invention are therefore suitable for use in technically usable full-color displays or white OLEDs as illuminants, or as emitters (preferably), matrix materials, charge transport materials, and/or charge blockers in OLEDs.

Compounds according to the invention also have comparatively low CIE x and CIE y values in the standard chromaticity diagram.

In the following, the invention is explained in more detail with reference to the figures and to compounds A-V, W, X and 3 to 12 according to the invention.

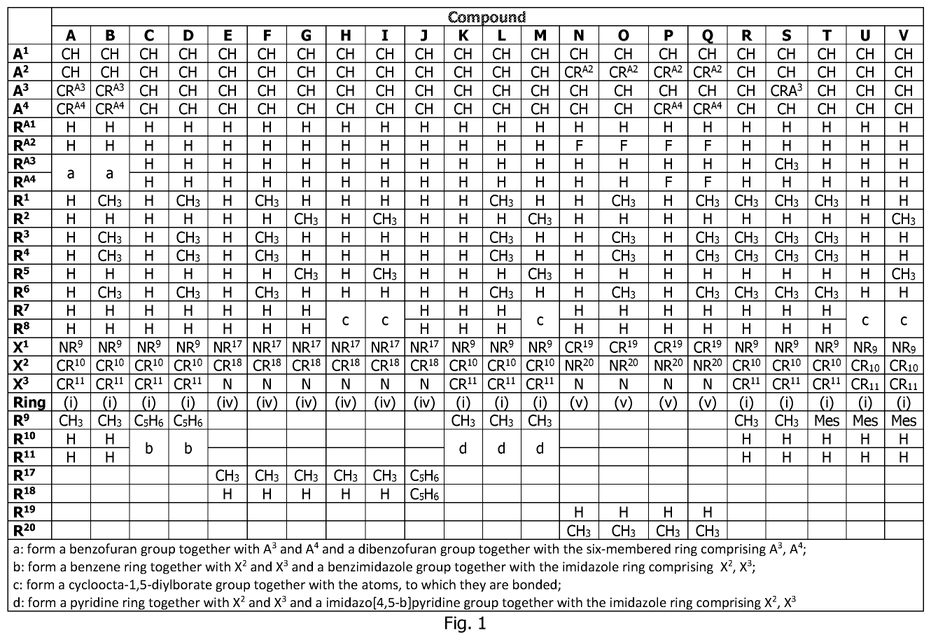

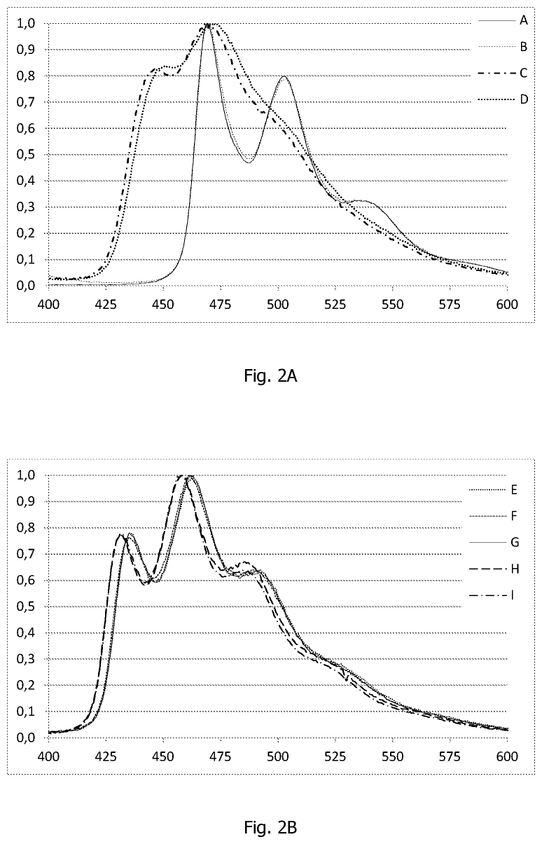

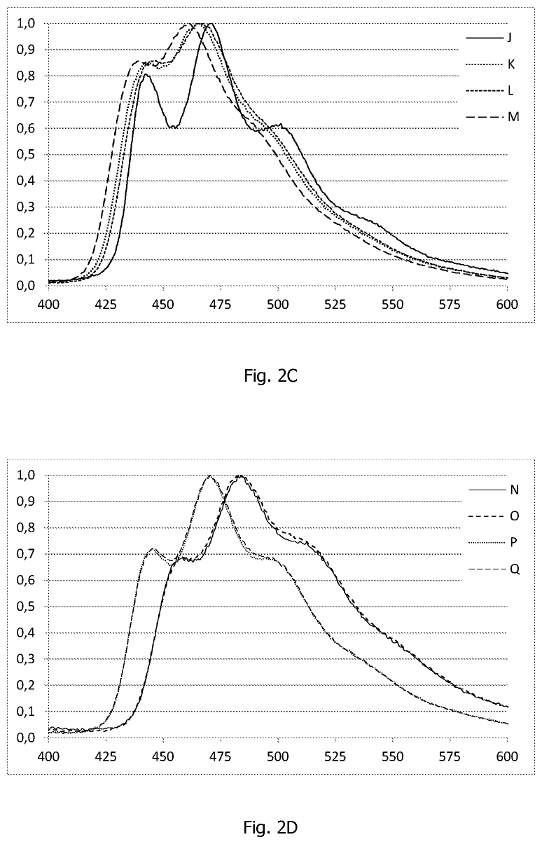

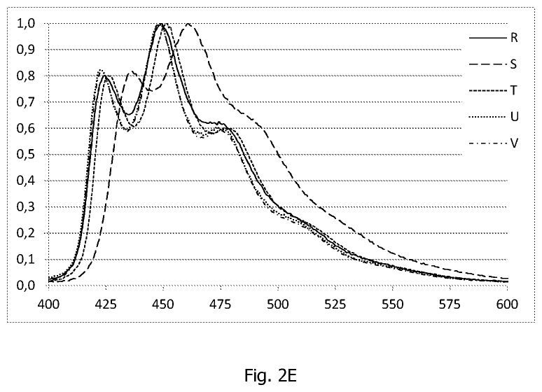

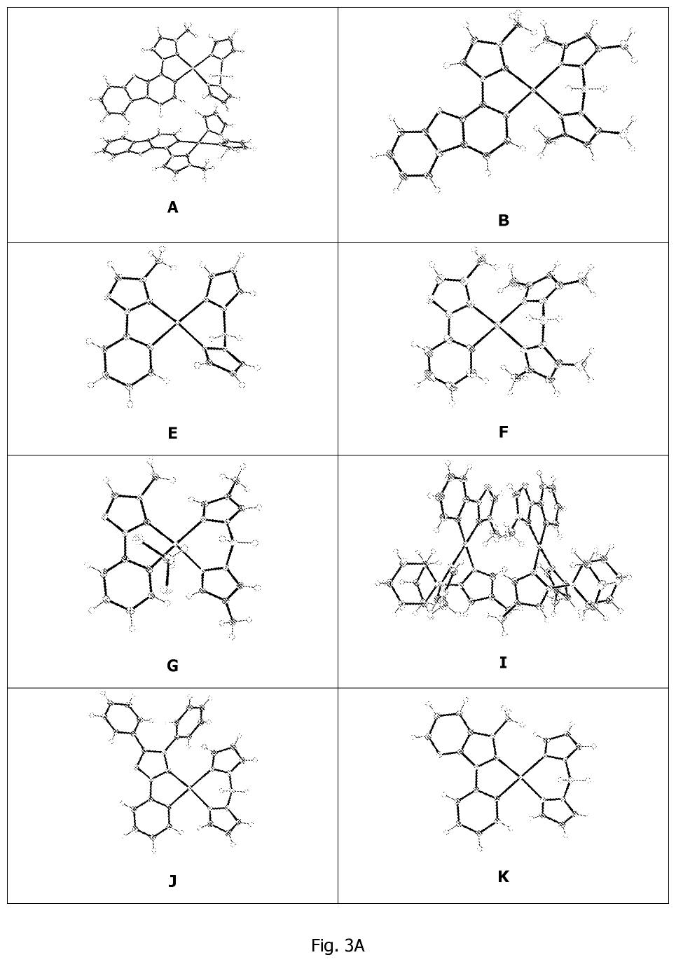

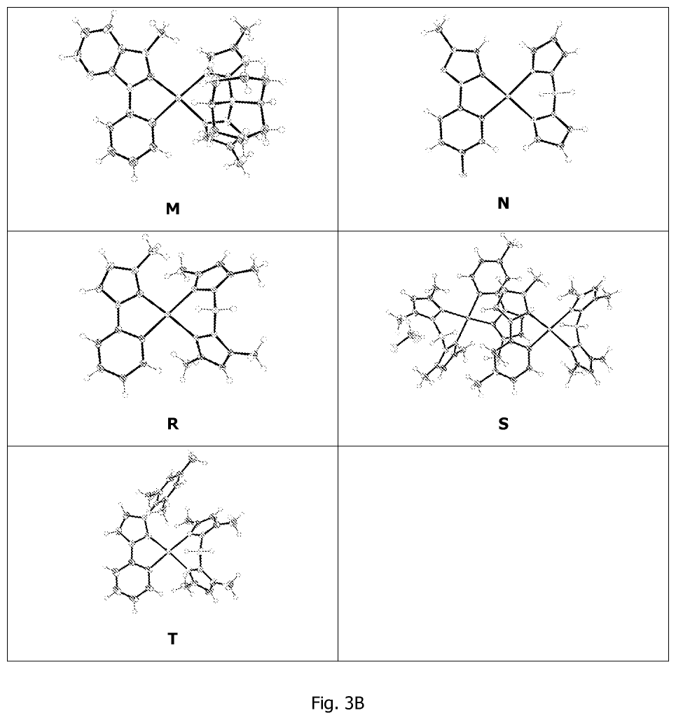

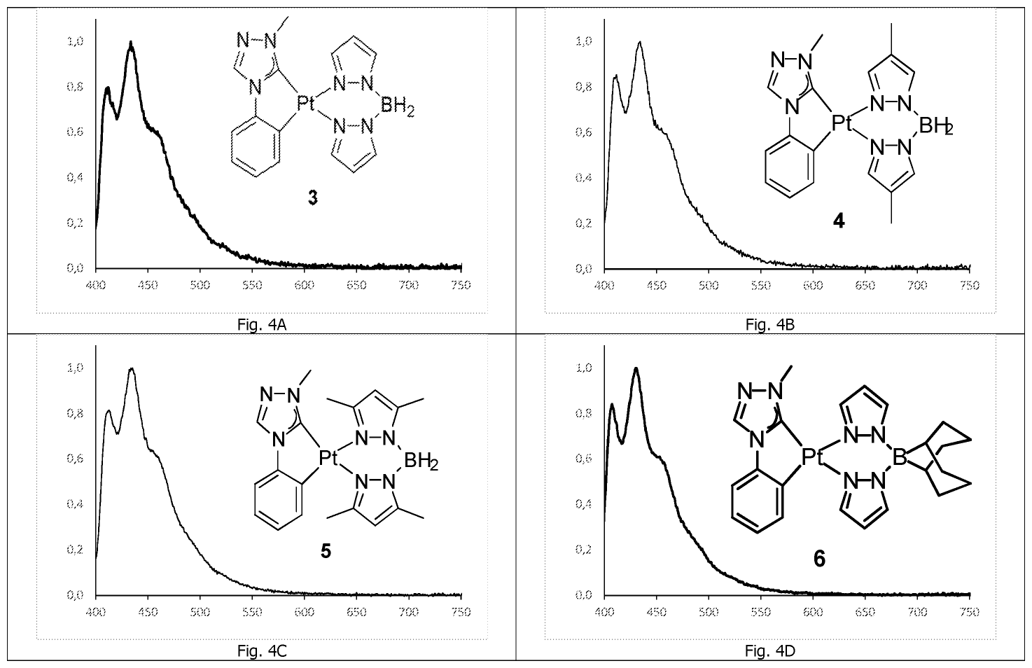

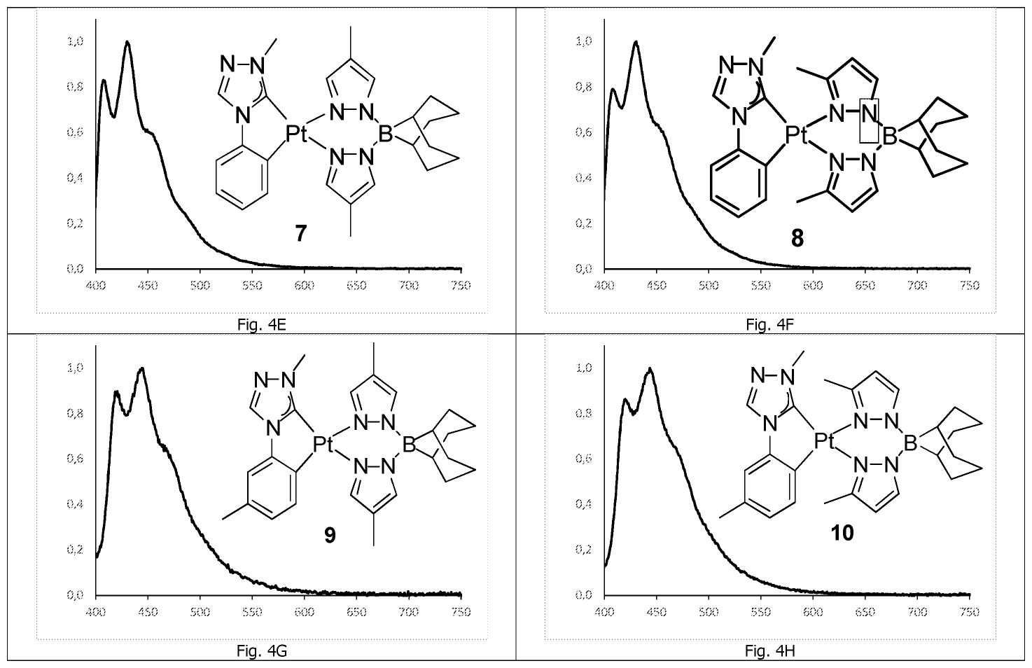

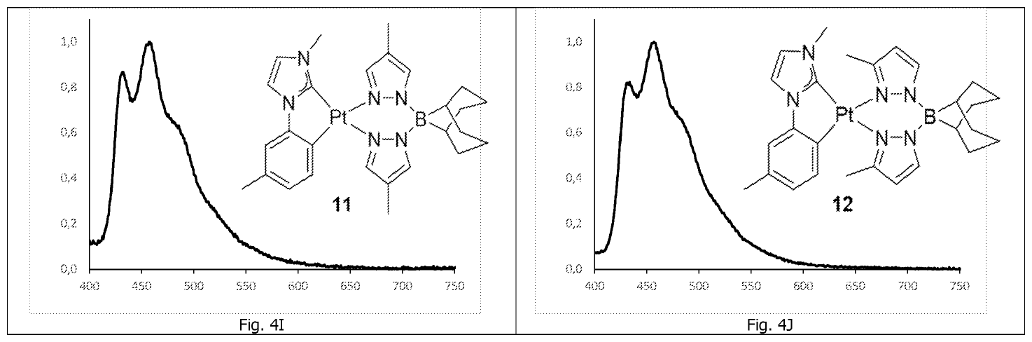

FIGS. 1 to 3B show: FIG. 1 a summary table showing how compounds A-V can be read under formula (I); FIG. 2A to 2E emission spectra of compounds A-V; FIG. 3A to 3B X-ray structures of compounds A, B, E, F, G, I, J, K, M, N, R, S, T; and FIG. 4A to 4I emission spectra of compounds 3 to 12.

Exemplary complexes according to the invention are: [1-(dibenzo[b,d]furan-4-yl-κC³)-3-methyl-1H-imidazolin-2-ylidene-κC²][dihydrobis(pyrazol-1-yl-κN²)borate]platinum(II) (A), [1-(dibenzo[b,d]furan-4-yl-κC³)-3-methyl-1H-imidazolin-2-ylidene-KC²][dihydrobis(3,5-dimethylpyrazol-1-yl-κN²)borate]platinum(II) (B), [dihydrobis(pyrazol-1-yl-KN²)borate][3-phenyl-1-(phenyl-κC²)-1H-benzimidazolin-2-ylidene-κC²]platinum(II) (C), [Dihydrobis(3,5-dimethylpyrazol-1-yl-KN²)borate][3-phenyl-1-(phenyl-κC²)-1H-benzimidazolin-2-ylidene-κC²]platinum(II) (D), [dihydrobis(pyrazol-1-yl-KN²)borate][4-methyl-1-(phenyl-κC²)-1H-1,2,4-triazol-5-ylidene-κC⁵]platinum(II) (E), [dihydrobis(3,5-dimethylpyrazol-1-yl-κN²)borate][4-methyl-1-(phenyl-κC²)-1H-1,2,4-triazol-5-ylidene-κC⁵]platinum(II) (F), [dihydrobis(4-methylpyrazol-1-yl-κN²)borate][4-methyl-1-(phenyl-κC²)-1H-1,2,4-triazol-5-ylidene-κC⁵]platinum(II) (Cᵢ), [Cycloocta-1,5-diylbis(pyrazol-1-yl-κN²)borate][4-methyl-1-(phenyl-κC²)-1H-1,2,4-triazol-5-ylidene-κC⁵]platinum(II) (H), [Cycloocta-1,5-diylbis(4-methylpyrazol-1-yl-κN²)borate][4-methyl-1-(phenyl-κC²)-1H-1,2,4-triazol-5-ylidene-κC⁵]platinum(II) (I), [dihydrobis(pyrazol-1-yl-κN²)borate][3,4-diphenyl-1-(phenyl-κC²)-1H-1,2,4-triazol-5-ylidene-κC⁵]platinum(II) (J), [dihydrobis(pyrazol-1-yl-κN²)borate][1-methyl-3-(phenyl-κC²)-1H-imidazo[4,5-b]pyridin-2-ylidene-κC²]platinum(II) (K), [dihydrobis(3,5-dimethylpyrazol-1-yl-κN²)borate][1-methyl-3-(phenyl-κC²)-1H-imidazo[4,5-b]pyridin-2-ylidene-κC²]platinum(II) (L), [cycloocta-1,5-diylbis(4-methylpyrazol-1-yl-κN²)borate][1-methyl-3-(phenyl-κC²)-1H-imidazo[4,5-b]pyridin-2-ylidene-κC²]platinum(II) (M), [dihydrobis(pyrazol-1-yl-κN²][3-(4-fluorophenyl-κC²)-1-methyl-1,2,3-triazol-4-ylidene-κC⁴]platinum(II) (N), [dihydrobis(3,5-dimethylpyrazol-1-yl-κN²)borate][3-(4-fluorophenyl-κC²)-1-methyl-1,2,3-triazol-4-ylidene-κC⁴]platinum(II) (O), [3-(2,4-difluorophenyl-κC⁶)-1-methyl-1,2,3-triazol-4-ylidene-κC⁴][dihydrobis(pyrazol-1-yl-κN²)borate]platinum(II) (P), [3-(2,4-difluorophenyl-κC⁶)-1-methyl-1,2,3-triazol-4-ylidene-κC⁴][dihydrobis(3,5-dimethylpyrazol-1-yl-κN²)borate]platinum(II) (Q), [dihydrobis(3,5-dimethylpyrazol-1-yl-κN²)borate][1-methyl-3-(phenyl-κC²)-1H-imidazolin-2-ylidene-κC²]platinum(II) (R), [dihydrobis(3,5-dimethylpyrazol-1-yl-κN²)borate][1-methyl-3-(5-methylphenyl-κC²)-1/imidazolin-2-ylidene-κC²]platinum(II) (S), [dihydrobis(3,5-dimethylpyrazol-1-yl-κN²)borate][1-(phenyl-κC²)-3-(2,4,6-trimethylphenyl)-1H-imidazolin-2-ylidene-κC²]platinum(II) (T), [cycloocta-1,5-diylbis(pyrazol-1-yl-κN²)borate][1-(phenyl-κC²)-3-(2,4,6-trimethylphenyl)-1H-imidazolin-2-ylidene-κC²]platinum(II) (U), [cycloocta-1,5-diylbis(4-methylpyrazol-1-yl-κN²)borate][1-(phenyl-κC²)-3-(2,4,6-trimethylphenyl)-1H-imidazolin-2-ylidene-κC²]platinum(II) (V); [dihydrobis(3,5-dimethylpyrazol-1-yl-κN²)borate][4-methyl-1-(5-methylphenyl-κC²)-1H-1,2,4-triazol-5-ylidene-κC⁵]platinum(II) (W); [cycloocta-1,5-diylbis(3-methylpyrazol-1-yl-κN²)borate][4-methyl-1-(phenyl-κC²)-1H-1,2,4-triazol-5-ylidene-κC⁵]platinum(II) (X); [dihydrobis(pyrazol-1-yl-κN²)borate][1-methyl-4-(phenyl-κC²)-1H-1,2,4-triazol-5-ylidene-κC⁵]platinum(II) (3); [Dihydrobis(4-methylpyrazol-1-yl-κN²)borate][1-methyl-4-(phenyl-κC²)-1H-1,2,4-triazol-5-ylidene-κC⁵]platinum(II) (4); [Dihydrobis(3,5-dimethylpyrazol-1-yl-κN²)borate][1-methyl-4-(phenyl-κC²)-1H-1,2,4-triazol-5-ylidene-κC⁵]platinum(II) (5); [cycloocta-1,5-diylbis(pyrazol-1-yl-κN²)borate][1-methyl-4-(phenyl-κC²)-1/H1,2,4-triazol-5-yliden-κC⁵]platinum(II) (6); [cycloocta-1,5-diylbis(4-methylpyrazol-1-yl-κN²)borate][1-methyl-4-(phenyl-κC²)-1H-1,2,4-triazol-5-ylidene-κC⁵]platinum(II) (7); [cycloocta-1,5-diylbis(3-methylpyrazol-1-yl-κN²)borate]-[1-methyl-4-(phenyl-κC²)-1H-1,2,4-triazol-5-ylidene-κC⁵]platinum(II) (8); [cycloocta-1,5-diylbis(4-methylpyrazol-1-yl-κN²)borate][1-methyl-4-(3-methylphenyl-κC²)-1H-1,2,4-triazol-5-ylidene-κC⁵]platinum(II) (9); [cycloocta-1,5-diylbis(3-methylpyrazol-1-yl-κN²)borate][1-methyl-4-(3-methylphenyl-κC²)-1H-1,2,4-triazol-5-ylidene-κC⁵]platinum(II) (10); [cycloocta-1,5-diylbis(4-methylpyrazol-1-yl-κN²)borate][3-methyl-1-(3-methylphenyl-κC²)-1H-imidazolin-2-ylidene-κC²]platinum(II) (11); [cycloocta-1,5-diylbis(3-methylpyrazol-1-yl-κN²)borate][3-methyl-1-(3-methylphenyl-κC²)-1H-imidazolin-2-ylidene-κC²]platinum(II) (12).

FIG. 1 shows the meanings A¹ to A⁴, R^{A1} to R^{A4}, R¹ to R²² and X¹ to X³ in the generic formula (I) for the complex compounds A-V in each case, and which ring according to alternatives (i) to (vi) is present in each case. The abbreviation Mes (complexes T-V) used in the table stands for mesityl or 2,4,6-trimethylphenyl.

The C\hat{ }C* ligand has an imidazole ring in complexes A-D, K-M and R-V (ring according to alternative (i)), a 1H-1,2,4-triazole ring in complexes E-J (ring according to alternative (iv)), and a 1,2,3-triazole ring in complexes N-Q (ring according to alternative (v)).

In complexes A and B, R^{A3} and R^{A4}, together with the atoms to which they are attached, each form a fused aromatic ring system in the form of a benzofuran system which, together with the remaining atoms of the six-membered ring of the C\hat{ }C* ligand having groups A¹ to A⁴, is part of a dibenzofuran group. In complexes C and D, R¹⁰ and R¹¹, together with the atoms to which they are attached, each form an unsaturated aromatic ring in the form of a benzene ring which, together with the remaining atoms of the imidazole ring of the C\hat{ }C* ligand, forms a benzimidazole group. In complexes H, I, M, U and V, R⁷ and R⁸ together with the atoms to which they are attached each form a cycloocta-1,5-diylborate group, and in complexes K, L and M, R¹⁰ and R¹¹ together with the atoms to which they are attached each form a pyridine ring which together with the remaining atoms of the imidazole ring of the C\hat{ }C* ligand each forms an imidazo[4,5-b]pyridine group.

Platinum(II) complexes according to the invention can be prepared by bringing suitable platinum compounds into contact with corresponding ligands or ligand precursors.

Suitable platinum compounds are all Pt salts or complexes known to those skilled in the art which exhibit sufficiently high reactivity. Preferred are corresponding Pt salts or complexes selected from the group consisting of Pt(COD)Cl₂ (COD=cycloocta-1,5-diene), Pt(PPh₃)₂Cl₂, Pt(pyridine)₂Cl₂, Pt(NH₃)₂Cl₂, Pt(acac)₂, PtCl₂, K₂PtCl₄ and mixtures thereof. Pt(COD)Cl₂ is particularly preferred.

Suitable ligands or ligand precursors are compounds which, after reaction with Pt compounds, yield the metal-carbene complexes of the above general formula (I). The ligands are, on the one hand, the desired C\hat{ }C* ligand in the form of an imidazole, triazole or thiazole ylidene and, on the other hand, the desired borate ligand.

Suitable C\hat{ }C* ligands or ligand precursors can be used in the form of salts of the following general formula (II):

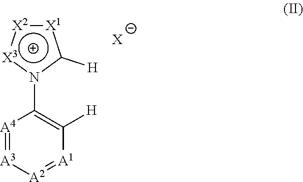

wherein X¹ to X³ and A¹ to A⁴ have the same meanings as described above in connection with formula (I), and X denotes an anion, such as a halide ion, in particular Cl⁻, Br⁻, I⁻, particularly preferably I⁻, or BF₄⁻, PF₆⁻, N(SO₂CF₃)₂⁻, SbF₆⁻, ClO₄⁻, ½ SO₄²⁻, preferably BF₄ or PF₆⁻, particularly preferably BF₄⁻.

Sufficient methods are available to those skilled in the art to provide, on the one hand, C\hat{ }C* ligands with appropriately substituted five-membered rings according to alternatives (i)-(vi) according to the invention and discussed above, and, on the other hand, bis(pyrazolyl)borate ligands for complexes according to the invention. Corresponding C\hat{ }C* ligands or ligand precursors and their preparation are known from literature, for example from:
(1) Unger, Y.; Meyer, D.; Molt, O.; Schildknecht, C.; Münster, I.; Wagenblast, G.; Strassner, T. Angew. Chem, Int. Ed. 2010, 49, 10214-10216;
(2) Tronnier, A.; Pöthig, A.; Metz, S.; Wagenblast, G.; Münster, I.; Strassner, T. Inorg. Chem. 2014, 53, 6346-6356;
(3) Tenne, M.; Metz, S.; Münster, I.; Wagenblast, G.; Strassner, T. Organometallics 2013, 32, 6257-6264;
(4) Strassner, T.; Unger, Y.; Meyer, D.; Molt, O.; Münster, I.; Wagenblast, G. Inorg. Chem. Commun. 2013, 30, 39-41;
(5) Pinter, P.; Mangold, H.; Stengel, I.; Münster, I.; Strassner, T. Organometallics 2016, 35, 673-680;
(6) Soellner, J.; Tenne, M.; Wagenblast, G.; Strassner, T. Chem.—Eur. J. 2016, 22, 9914-9918;
(7) Aghazada, S.; Zimmermann, I.; Scutelnic, V.; Nazeeruddin, M. K. Organometallics 2017, 36, 2397-2403;
(8) Lv, T.; Wang, Z.; You, J.; Lan, J.; Gao, G. J. Org. Chem. 2013, 78, 5723-5730;
(9) J. Soellner, T. Strassner, Chem. Eur. J. 2018, 24, 15603-15612; and
(10) H. Leopold, A. Tronnier, G. Wagenblast, I. Münster, T. Strassner, Organometallics 2016, 35, 959-971.

The literature mentioned describes C\hat{ }C* ligands with five-membered rings according to all alternatives (i) to (vi). C\hat{ }C* ligands with five-membered rings according to alternatives (i) to (vi) which are not known from the literature can be prepared, for example, following known preparation instructions for comparable compounds using appropriately modified reactants.

| C\hat{ }C*ligands with a five-membered | known from |
|---|---|
| ring according to alternative | literature |
| (i) | (1), (2), (5), (7), (8) |
| (ii) | (9) |
| (iii) | (3), (4) |
| (iv) | (3) |
| (v) | (6) |
| (vi) | (10) |

Bis(pyrazolyl)borate ligands or their precursors can be purchased or prepared by known methods. Bis(pyrazolyl)borate ligands including their preparation result for example from
(11) S. Trofimenko, J. C. Calabrese, J. S. Thompson, Inorg. Chem. 1992, 31, 974-979;
(12) S. Trofimenko, J. Am. Chem. Soc. ACS 1967, 89 (13), 3170-3177;
(13) R. J. Abernethy, A. F. Hill, M. K. Smith, A. C. Willis, Organometallics 2009, 28, 6152-6159 (DOI: 10.1021/om9006592);
(14) E. Craven, E. Mutlu, D. Lundberg, S. Temizdemir, S. Dechert, H. Brombacher, C. Janiak, Polyhedron 2002, 21, 553-562; and.
(15) S. Trofimenko, J. Am. Chem. Soc. ACS 1966, 88 (8), 1842-1844.

### EXAMPLES

The following examples, in particular the methods, reagents, reaction conditions, process parameters, apparatus and the like described therein, are provided for the purpose of illustrating the present invention and are not to be construed as narrowing the invention. Percentages given herein or otherwise in connection with the invention are in weight % and any ratios given are weight ratios unless otherwise indicated. Superscript numbers at the respective C\hat{ }C* ligand precursors refer to references (1) through (8) above.

### General Synthesis Rule

In a heated Schlenk tube, 1 eq of the appropriate C\hat{ }C* ligand precursor and 0.5 eq of silver(I) oxide are placed under an argon atmosphere and suspended in DMF. The mixture is stirred at the indicated temperature (T₁) for 21 h. Subsequently, 1 eq of Pt(COD)Cl₂ is added and stirring is carried out first for 3 h at room temperature and later for 21 h at the indicated temperature (T₂). In the following, 2 eq of the corresponding bis(pyrazolyl)borate ligand is added at room temperature and the reaction is stirred for 21 h at 50° C. At the end of the reaction time, all volatiles are removed under high vacuum, the residue is extracted with dichloromethane (DCM) and the extract is filtered over Celite. Purification is carried out by column chromatography on silica gel 60 with the indicated eluent or a mixture of eluents adapted to the polarity. Appropriate eluent mixtures can be prepared, for example, from dichloromethane (DCM) and iso-hexane, the mixing ratio being adapted to the polarity. The solid obtained is washed with iso-hexanes and diethyl ether and dried under high vacuum.

### [1-(Dibenzo[b,d]furan-4-yl-κC³)-3-methyl-1/imidazolin-2-ylidene-κC²][dihydrobis(pyrazol-1-yl-κN²)borate]platinum(II) (A)

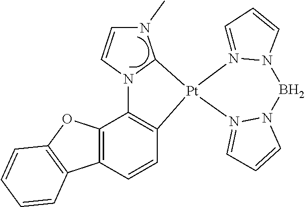

Synthesis analogous to the general synthesis procedure. 0.301 g (0.8 mmol) 1-(dibenzo[b,d]furan-4-yl)-3-methyl-1H-imidazolium iodide, and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.298 g (1.6 mmol, 2 eq) potassium dihydrobis(pyrazol-1-yl)borate is added. Eluent mixture: iso-hexane/DCM (2:3). Yield: 257 mg (55%); melting point: 239° C.; molecular formula: C₂₂H₁₉BN₆OPt; molar mass: 589.32 g/mol. 1H NMR in CDCl₃ (600 MHz): δ=8.14 (d, J=2.0 Hz, 1H, CHₐᵣₒₘ), 7.93-7.88 (m, 1H, CHₐᵣₒₘ), 7.80 (d, J=2.1 Hz, 1H, CHₐᵣₒₘ), 7.73 (d, J=2.0 Hz, 1H, CHₐᵣₒₘ), 7.66 (d, J=2.3 HZ, 1H, CHₐᵣₒₘ), 7.65 (d, J=2.3 Hz, 1H, CHₐᵣₒₘ), 7.60-7.55 (m, 1H, CHₐᵣₒₘ), 7.55 (d, J=8.2 Hz, 1H, CHₐᵣₒₘ), 7.46-7.41 (m, 1H, CHₐᵣₒₘ), 7.37-7.30 (m, 2H, CHₐᵣₒₘ), 6.89 (d, J=2.0 Hz, 1H, CHₐᵣₒₘ), 6.29 (t, J=2.2 Hz, 1H, CHₐᵣₒₘ), 6.21 (t, J=2.2 Hz, 1H, CHₐᵣₒₘ), 3.65 (s, 3H, NCH₃). ¹³C NMR in CDCl₃ (151 MHz): δ=157.5 (Cᵢ), 155.9 (Cᵢ), 142.8 (Cᵢ), 142.2 (CHₐᵣₒₘ), 141.4 (CHₐᵣₒₘ), 136.3 (CHₐᵣₒₘ), 136.1 (CHₐᵣₒₘ), 131.2 (Cᵢ), 129.5 (Cᵢ), 129.4 (CHₐᵣₒₘ), 126.6 (CHₐᵣₒₘ), 124.8 (Cᵢ), 123.1 (CHₐᵣₒₘ), 122.9 (Cᵢ), 121.5 (CHₐᵣₒₘ), 120.5 (CHₐᵣₒₘ), 118.7 (CHₐᵣₒₘ), 116.2 (CHₐᵣₒₘ), 111.5 (CHₐᵣₒₘ), 105.2 (CHₐᵣₒₘ), 105.1 (CHₐᵣₒₘ), 37.6 (NCH₃). ¹⁹⁵Pt NMR in CDCl₃ (64 MHz): δ=−3810.7 (s). MS (ESI): m/z=588.4 [M−H]⁺, 1196.4 [2M+NH₄]⁺. Elemental analysis: calculated C, 44.84%; H, 3.25%; N, 14.26%; found C, 44.69%; H, 2.92%; N, 14.09%.

### [1-(Dibenzo[b,d]furan-4-yl-κC³)-3-methyl-1H-imidazolin-2-ylidene-κC²][dihydrobis(3,5-dimethylpyrazol-1-yl-κN²)borate]platinum(II) (B)

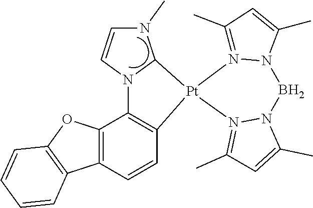

Synthesis analogous to the general synthesis procedure. 0.301 g (0.8 mmol) 1-(dibenzo[b,d]furan-4-yl)-3-methyl-1H-imidazolium iodide, and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent mixture: iso-hexane/DCM (1:2). Yield: 120 mg (23%); melting point: 279° C.; molecular formula: C₂₆H₂₇BN₆OPt; molar mass: 645.43 g/mol. 1H NMR in CDCl₃ (300 MHz): δ=8.11 (d, J=2.0 Hz, 1H, CHₐᵣₒₘ), 7.88 (dd, J=7.2, 1.2 Hz, 1H, CHₐᵣₒₘ), 7.62-7.45 (m, 2H, CHₐᵣₒₘ), 7.41 (td, J=8.2, 7.8, 1.4 Hz, 1H, CHₐᵣₒₘ), 7.31 (td, J=7.5, 1.1 Hz, 1H, CHₐᵣₒₘ), 7.27-7.21 (m, 1H, CHₐᵣₒₘ), 6.88 (d, J=2.1 Hz, 1H, CHₐᵣₒₘ), 5.83 (s, 1H, CHₐᵣₒₘ), 5.77 (s, 1H, CHₐᵣₒₘ), 3.58 (s, 3H, NCH₃), 2.35 (s, 3H, CCH₃), 2.33 (s, 3H, CCH₃), 2.30 (s, 3H, CCH₃), 2.29 (s, 3H, CCH₃). ¹³C NMR in CDCl₃ (75 MHz): δ=158.4 (Cᵢ), 155.8 (Cᵢ), 147.9 (Cᵢ), 147.8 (Cᵢ), 145.3 (Cᵢ), 145.0 (Cᵢ), 142.8 (Cᵢ), 131.2 (Cᵢ & CHₐᵣₒₘ), 130.4 (Cᵢ), 126.3 (CHₐᵣₒₘ), 125.0 (Cᵢ), 122.9 (CHₐᵣₒₘ), 122.3 (Cᵢ), 121.1 (CHₐᵣₒₘ), 120.4 (CHₐᵣₒₘ), 118.6 (CHₐᵣₒₘ), 115.9 (CHₐᵣₒₘ), 111.4 (CHₐᵣₒₘ), 105.7 (CHₐᵣₒₘ), 105.2 (CHₐᵣₒₘ), 35.8 (NCH₃), 15.4 (CCH₃), 14.6 (CCH₃), 13.0 (CCH₃), 12.9 (CCH₃). ¹⁹⁵Pt NMR in CDCl₃ (64 MHz): δ=−3837.5 (s). MS (ESI): m/z=646.4 [M−H]⁺. Elemental analysis: calculated C, 48.38%; H, 4.22%; N, 13.02%; found C, 48.06%; H, 4.03%; N, 12.84%.

### [Dihydrobis(pyrazol-1-yl-κN²)borate][3-phenyl-1-(phenyl-κC²)-1H-benzimidazolin-2-ylidene-κC²]platinum(II) (C)

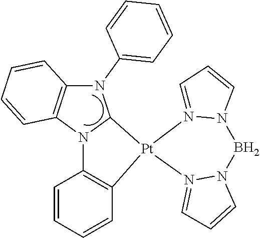

Synthesis analogous to the general synthesis procedure. 0.287 g (0.8 mmol) 1,3-diphenyl-1H-benzimidazolium tetrafluoroborate² and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.298 g (1.6 mmol, 2 eq) potassium dihydrobis(pyrazol-1-yl)borate is added. Eluent mixture: iso-hexane/DCM (5:4). Yield: 154 mg (58%); melting point: 258° C.; molecular formula: C₂₅H₂₁BN₆Pt; molar mass: 611.37 g/mol. 1H NMR in DMSO-d₆ (300 MHz): δ=8.47 (d, J=8.2 Hz, 1H, CHₐᵣₒₘ), 7.96 (d, J=7.8 HZ, 1H, CHₐᵣₒₘ), 7.83-7.67 (m, 3H, CHₐᵣₒₘ), 7.61-7.51 (m, 2H, CHₐᵣₒₘ), 7.50-7.37 (m, 3H, CHₐᵣₒₘ), 7.37-7.31 (m, 2H, CHₐᵣₒₘ), 7.31-7.20 (m, 3H, CHₐᵣₒₘ), 7.04 (t, J=7.4 Hz, 1H, CHₐᵣₒₘ), 6.86 (d, J=2.1 HZ, 1H, CHₐᵣₒₘ), 6.36 (t, J=2.2 Hz, 1H, CHₐᵣₒₘ), 5.52 (t, J=2.2 Hz, 1H, CHₐᵣₒₘ). ¹³C NMR in DMSO-d₆ (75 MHz): δ=166.2 (Cᵢ), 148.5 (Cᵢ), 141.2 (CHₐᵣₒₘ), 141.1 (CHₐᵣₒₘ), 136.2 (CHₐᵣₒₘ), 135.5 (Cᵢ), 135.1 (Cᵢ), 134.1 (CHₐᵣₒₘ), 134.0 (CHₐᵣₒₘ), 131.3 (Cᵢ), 130.4 (Cᵢ), 128.8 (CHₐᵣₒₘ), 128.6 (2CHₐᵣₒₘ) 125.4 (CHₐᵣₒₘ), 124.2 (2CHₐᵣₒₘ), 124.1 (CHₐᵣₒₘ), 112.7 (CHₐᵣₒₘ), 112.1 (CHₐᵣₒₘ), 112.0 (CHₐᵣₒₘ), 105.5 (CHₐᵣₒₘ), 105.0 (CHₐᵣₒₘ). ¹⁹⁵Pt NMR in DMSO-d₆ (64 MHz): δ=−3783.2 (s). MS (ESI): m/z=612.4 [M−H]+, 1240.4 [2M+NH₄]⁺. Elemental analysis: calculated C, 49.11%; H, 3.46%; N, 13.75%; found C, 49.12%; H, 3.56%; N, 13.66%.

### [Dihydrobis(3,5-dimethylpyrazol-1-yl-κN²)borate][3-phenyl-1-(phenyl-κC²)-1/benzimidazolin-2-ylidene-κC²]platinum(II) (D)

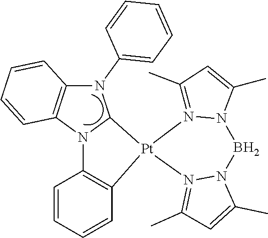

Synthesis analogous to the general synthesis procedure. 0.287 g (0.8 mmol) 1,3-diphenyl-1H-benzimidazolium tetrafluoroborate² and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent mixture: iso-hexane/DCM (5:4). Yield: 54 mg (10%); melting point: 269° C.; molecular formula: C₂₉H₂₉BN₆Pt; molar mass: 667.48 g/mol. ¹H NMR in CD₂Cl₂ (300 MHz): δ=8.13 (d, J=8.2 Hz, 1H, CHₐᵣₒₘ), 7.78-7.65 (m, 1H, CHₐᵣₒₘ), 7.62 (dd, J=8.3, 1.4 HZ, 2H, CHₐᵣₒₘ), 7.48 (m, 1H, CHₐᵣₒₘ), 7.44-7.28 (m, 4H, CHₐᵣₒₘ), 7.28-7.03 (m, 3H, CHₐᵣₒₘ), 6.97 (td, J=7.4, 1.1 Hz, 1H, CHₐᵣₒₘ), 5.84 (s, 1H, CHₐᵣₒₘ), 5.07 (s, 1H, CHₐᵣₒₘ), 2.31 (s, 3H, CCH₃), 2.25 (s, 3H, CCH₃), 2.19 (s, 3H, CCH₃), 1.75 (s, 3H, CCH3). ¹³C NMR in CD₂Cl₂ (75 MHz): δ=169.0 (Cᵢ), 149.6 (Cᵢ), 148.2 (Cᵢ), 147.2 (Cᵢ), 145.8 (Cᵢ), 144.5 (Cᵢ), 136.9 (CHₐᵣₒₘ), 136.2 (Cᵢ), 136.0 (Cᵢ), 132.6 (Cᵢ), 132.1 (Cᵢ), 129.0 (CHₐᵣₒₘ), 125.4 (CHₐᵣₒₘ), 124.4 (CHₐᵣₒₘ), 124.2 (CHₐᵣₒₘ), 124.0 (CCHₐᵣₒₘ), 112.4 (CHₐᵣₒₘ), 112.4 (CHₐᵣₒₘ), 112.1 (CHₐᵣₒₘ), 106.1 (CHₐᵣₒₘ), 105.3 (CHₐᵣₒₘ), 15.5 (CCH₃), 14.7 (CCH₃), 13.2 (CCH₃), 12.6 (CCH₃). ¹⁹⁵Pt NMR in CD₂Cl₂ (64 MHz): δ=−3790.6 (s). MS (ESI): m/z=668.5 [M−H]+, 685.4 [M+NH₄]⁺. Elemental analysis: calculated C, 52.18%; H, 4.38%; N, 12.59%; found C, 51.90%; H, 4.38%; N, 12.44%.

### [Dihydrobis(pyrazol-1-yl-κN²)borate][4-methyl-1-(phenyl-κC²)-1H-1,2,4-triazol-5-ylideneκC⁵]platinum(II) (E)

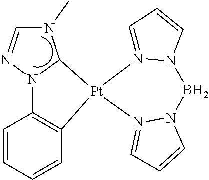

Synthesis analogous to the general synthesis procedure. 230 mg (0.8 mmol) 4-methyl-1-phenyl-1H-1,2,4-triazolium iodide³ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 298 mg (1.6 mmol, 2 eq) potassium dihydrobis(pyrazol-1-yl)borate is added. Eluent mixture: iso-hexane/DCM (1:6). Yield: 206 mg (52%); melting point: 231° C.; molecular formula: C₁₅H₁₆BN₇Pt; molar mass: 500.23 g/mol. 1H NMR in DMSO-d₆ (300 MHz, DMSO-d₆): δ=8.78 (s, 1H), 8.09 (dd, J=2.1, 0.7 Hz, 1H), 7.79 (d, J=2.2 Hz, 1H), 7.76 (d, J=2.4 Hz, 2H), 7.31 (dd, J=7.6, 1.4 Hz, 1H), 7.23 (dd, J=7.5, 1.3 Hz, 1H), 7.13 (td, J=7.5, 1.3 Hz, 1H), 7.00 (td, J=7.4, 1.4 Hz, 1H), 6.38 (t, J=2.2 Hz, 1H), 6.30 (t, J=2.2 Hz, 1H), 3.64 (s, 3H). ¹³C NMR in DMSO-d₆ (75 MHz): δ=158.2 (Cᵢ), 145.6 (Cᵢ), 144.8 (CHₐᵣₒₘ), 143.4 (CHₐᵣₒₘ), 141.3 (CHₐᵣₒₘ), 136.2 (CHₐᵣₒₘ), 136.1 (CHₐᵣₒₘ), 133.9 (CHₐᵣₒₘ), 126.3 (Cᵢ), 125.2 (CHₐᵣₒₘ), 124.1 (CHₐᵣₒₘ), 111.5 (CHₐᵣₒₘ), 105.6 (CHₐᵣₒₘ), 105.4 (CHₐᵣₒₘ), 34.6 (NCH₃). ¹⁹⁵Pt NMR in DMSO-d₆ (64 MHz): δ=−3868.3 (s). MS (ESI): m/z=499.3 [M−H]⁺. Elemental analysis: calculated C, 36.02%; H, 3.22%; N, 19.60%; found C, 36.39%; H, 3.20%; N, 19.23%.

### [Dihydrobis(3,5-dimethylpyrazol-1-yl-κN²)borate][4-methyl-1-(phenyl-κC²)-1H-1,2,4-triazol-5-ylidene-κC⁵]platinum(II) (F)

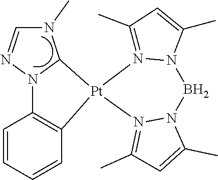

Synthesis analogous to the general synthesis procedure. 0.230 g (0.8 mmol) 4-methyl-1-phenyl-1H-1,2,4-triazolium iodide³ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent: DCM. Yield: 85 mg (19%); melting point: 241° C.; molecular formula: C₁₉H₂₄BN₇Pt; molar mass: 556.34 g/mol. ¹H NMR in CDCl₃ (300 MHz): δ=7.84 (s, 1H, CHₐᵣₒₘ), 7.34 (dd, J=7.7, 1.4 Hz, 1H, CHₐᵣₒₘ), 7.28 (dd, J=7.6, 1.4 Hz, 1H, CHₐᵣₒₘ), 7.09 (td, J=7.5, 1.4 Hz, 1H, CHₐᵣₒₘ), 6.96 (td, J=7.4, 1.4 Hz, 1H, CHₐᵣₒₘ), 5.81 (s, 1H, CHₐᵣₒₘ), 5.77 (s, 1H, CHₐᵣₒₘ), 3.57 (s, 3H, NCH₃), 2.32 (s, 3H, CCH₃), 2.31 (s, 3H, CCH₃), 2.29 (s, 3H, CCH3), 2.25 (s, 3H, CCH₃). ¹³C NMR in CDCl₃ (151 MHz): δ=161.2 (Cᵢ), 147.7 (Cᵢ), 147.6 (Cᵢ), 145.9 (Cᵢ), 145.4 (Cᵢ), 145.0 (Cᵢ), 141.9 (CHₐᵣₒₘ), 136.4 (CHₐᵣₒₘ), 126.64, 125.4 (CHₐᵣₒₘ), 123.9 (CHₐᵣₒₘ), 111.8 (CHₐᵣₒₘ), 105.6 (CHₐᵣₒₘ), 105.1 (CHₐᵣₒₘ), 33.2 (NCH₃), 15.2 (CCH₃), 14.6 (CCH₃), 12.8 (2CCH₃). ¹⁹⁵Pt NMR in CDCl₃ (64 MHz): δ=−3884.4 (s). MS (ESI): m/z=555.4 [M−H]⁺, 1130.6 [2M+NH₄]⁺. Elemental analysis: calculated C, 41.02%; H, 4.35%; N, 17.62%; found C, 40.83%; H, 4.51%; N, 17.36%.

### [Dihydrobis(4-methylpyrazol-1-yl-κN²)borate][4-methyl-1-(phenyl-κC²)-1H-1,2,4-triazol-5-ylidene-κC⁵]platinum(II) (G)

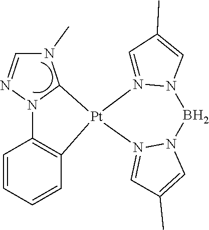

Synthesis analogous to the general synthesis procedure. 0.230 g (0.8 mmol) 4-methyl-1-phenyl-1H-1,2,4-triazolium iodide³ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.343 g (1.6 mmol, 2 eq) potassium dihydrobis(4-methylpyrazol-1-yl)borate is added. Eluent mixture: iso-hexane/DCM (1:5). Yield: 164 mg (39%); melting point: 248° C.; molecular formula: C₁₇H₂₀BN₇Pt; molar mass: 528.28 g/mol. 1H NMR in CDCl₃ (600 MHz): δ=7.85 (s, 1H, CHₐᵣₒₘ), 7.54 (s, 1H, CHₐᵣₒₘ), 7.47 (s, 1H, CHₐᵣₒₘ), 7.43-7.40 (m, 2H, CHₐᵣₒₘ), 7.39 (s, 1H, CHₐᵣₒₘ), 7.37 (dd, J=7.7, 1.3 Hz, 1H, CHₐᵣₒₘ), 7.14 (td, J=7.5, 1.3 Hz, 1H, CHₐᵣₒₘ), 7.06 (td, J=7.4, 1.4 Hz, 1H, CHₐᵣₒₘ), 3.70 (s, 3H, NCH3), 2.10 (s, 3H, CCH3), 2.03 (s, 3H, CCH₃ ¹³C NMR in CDCl₃ (151 MHz): δ=160.8 (C), 146.1 (Cᵢ), 142.2 (CHₐᵣₒₘ), 141.8 (CHₐᵣₒₘ), 140.9 (CHₐᵣₒₘ), 135.8 (CHₐᵣₒₘ), 135.6 (CHₐᵣₒₘ), 134.8 (CHₐᵣₒₘ), 126.2 (Cᵢ), 125.8 (CHₐᵣₒₘ), 124.4 (CHₐᵣₒₘ), 115.5 (Cᵢ), 115.4 (Cᵢ), 112.3 (CHₐᵣₒₘ), 35.0 (NCH₃), 9.1 (CCH₃), 9.0 (CCH₃). ¹⁹⁵Pt NMR in CDCl₃ (64 MHz): δ=−3857.2 (s). MS (ESI): m/z=529.3 [M+H]⁺, 546.3 [M+NH₄]⁺. Elemental analysis: calculated C, 38.65%; H, 3.82%; N, 18.56%; found C, 38.62%; H, 3.81%; N, 18.45%.

### [Cycloocta-1,5-diylbis(pyrazol-1-yl-κN²)borate][4-methyl-1-(phenyl-κC²)-1H-1,2,4-triazol-5-ylidene-κC⁵]platinum(II) (H)

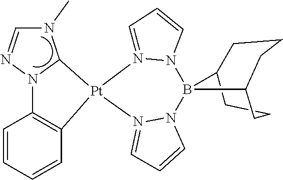

Synthesis analogous to the general synthesis procedure. 0.230 g (0.8 mmol) 4-methyl-1-phenyl-1H-1,2,4-triazolium iodide³ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.471 g (1.6 mmol, 2 eq) potassium cycloocta-1,5-diylbis(pyrazol-1-yl)borate is added. Eluent mixture: iso-hexane/DCM (2:5). Yield: 80 mg (16%); melting point: 301° C.; molecular formula: C₂₃H₂₈BN₇Pt; molar mass: 608.41 g/mol. ¹H NMR in CDCl₃ (600 MHz): δ=7.89 (s, 1H, CHₐᵣₒₘ), 7.81-7.74 (m, 3H, CHₐᵣₒₘ), 7.70 (dd, J=2.0, 0.7 Hz, 1H, CHₐᵣₒₘ), 7.56-7.41 (m, 1H, CHₐᵣₒₘ), 7.39 (dd, J=7.7, 1.3 Hz, 1H), 7.15 (td, J=7.6, 1.3 HZ, 1H, CHₐᵣₒₘ), 7.06 (td, J=7.4, 1.4 Hz, 1H, CHₐᵣₒₘ), 6.24 (t, J=2.2 Hz, 1H, CHₐᵣₒₘ), 6.19 (t, J=2.2 Hz, 1H, CHₐᵣₒₘ), 3.76 (s, 3H, NCH₃), 3.58-3.51 (m, 1H, CH_{9-BBN}), 2.29-2.20 (m, 2H, CH_{2, 9-BBN}), 2.06-1.85 (m, 4H, CH_{2, 9-BBN}), 1.75-1.58 (m, 2H, CH_{2, 9-BBN}), 1.52-1.40 (m, 5H, C/2, 9-BBN & C-BBN). ¹³C NMR in CDCl₃ (151 MHz): δ=161.1 (Cᵢ), 145.8 (Cᵢ), 142.1 (CHₐᵣₒₘ), 141.5 (CHₐᵣₒₘ), 141.2 (CHₐᵣₒₘ), 134.5 (CHₐᵣₒₘ), 134.3 (CHₐᵣₒₘ), 134.2 (CHₐᵣₒₘ), 126.4 (Cᵢ), 125.9 (CHₐᵣₒₘ), 124.2 (CHₐᵣₒₘ), 112.4 (CHₐᵣₒₘ), 105.1 (CHₐᵣₒₘ), 104.8 (CHₐᵣₒₘ), 34.8 (NCH₃), 32.5 (CH_{2, 9-BBN}), 32.3 (CH_{2, 9-BBN}), 31.3 (CH_{2, 9-BBN}), 30.3 (CH_{2, 9-BBN}), 24.7 (CH_{2, 9-BBN}), 24.6 (CH_{2, 9-BBN}). ¹⁹⁵Pt NMR in CDCl₃ (129 MHz): δ=−3766.3 (s). MS (ESI): m/z=609.3 [M−H]⁺, 1234.4 [2M+NH₄]⁺. Elemental analysis: calculated C, 45.40%; H, 4.64%; N, 16.11%; found C, 45.43%; H, 4.63%; N, 16.03%.

### [Cycloocta-1,5-diylbis(4-methylpyrazol-1-yl-κN²)borate][4-methyl-1-(phenyl-κC²)-1H-1,2,4-triazol-5-ylidene-κC⁵]platinum(II) (I)

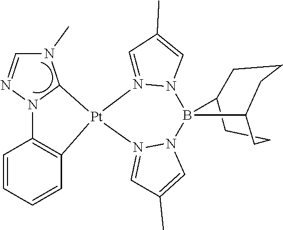

Synthesis analogous to the general synthesis procedure. 0.230 g (0.8 mmol) 4-methyl-1-phenyl-1H-1,2,4-triazolium iodide³ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.516 g (1.6 mmol, 2 eq) potassium cycloocta-1,5-diylbis(4-methylpyrazol-1-yl)borate is added. Eluent mixture: iso-hexane/DCM (2:5).

Yield: 235 mg (46%); melting point: 241° C. (dec.); molecular formula: C₂₅H₃₂BN₇Pt; molar mass: 636.47 g/mol. ¹H NMR in CDCl₃ (600 MHz): δ=7.87 (s, 1H, CHₐᵣₒₘ), 7.55 (s, 1H, CHₐᵣₒₘ), 7.53 (s, 1H, CHₐᵣₒₘ), 7.53 (s, 1H, CHₐᵣₒₘ), 7.50 (dd, J=7.5, 1.3 Hz, 1H, CHₐᵣₒₘ), 7.48 (s, 1H, CHₐᵣₒₘ), 7.38 (dd, J=7.7, 1.3 Hz, 1H, CHₐᵣₒₘ), 7.14 (td, J=7.5, 1.3 Hz, 1H, CHₐᵣₒₘ), 7.06 (td, J=7.4, 1.4 Hz, 1H, CHₐᵣₒₘ), 3.76 (s, 3H, NCH3), 3.45 (bs, 1H, CH_{9-BBN}), 2.28-2.19 (m, 2H, CH_{2,9-BBN}), 2.07 (s, 3H, CCH₃), 2.02 (s, 3H, CCH₃), 2.01-1.91 (m, 2H, CH_{2, 9-BBN}), 1.91-1.84 (n, 2H, CH_{2, 2, 9-BBN}), 1.73-1.66 (n, 1H, CH_{2, 9-BBN}), 1.63-1.58 (m, 1H, CH_{2, 9-BBN}), 1.52-1.42 (m, 4H, CH_{2, 9-BBN}), 1.35 (bs, 1H, CH_{9-BBN}). ¹³C NMR in CDCl₃ (151 MHz): δ=161.5 (Cᵢ), 145.8 (Cᵢ), 142.0 (CHₐᵣₒₘ), 141.2 (CHₐᵣₒₘ), 140.8 (CHₐᵣₒₘ), 134.4 (CHₐᵣₒₘ), 133.9 (CHₐᵣₒₘ), 133.6 (CHₐᵣₒₘ), 126.8 (Cᵢ), 125.8 (CHₐᵣₒₘ), 124.1 (CHₐᵣₒₘ), 115.1 (Cᵢ), 114.8 (Cᵢ), 112.3 (CHₐᵣₒₘ), 34.8 (NCH₃), 32.6 (CH₂), 32.4 (CH₂), 31.3 (CH₂), 30.4 (CH₂), 24.7 (CH₂), 24.7 (CH₂), 9.2 (2CCH₃). ¹⁹⁵Pt NMR in CDCl₃ (129 MHz): δ=−3757.1 (s). MS (ESI): m/z=637.4 [M+H]⁺. Elemental analysis: calculated C, 47.18%; H, 5.07%; N, 15.40%; found C, 47.09%; H, 5.19%; N, 15.08%.

### [Dihydrobis(pyrazol-1-yl-κN²)borate][3,4-diphenyl-1-(phenyl-κC²)-1H-1,2,4-triazol-5-ylidene-κC⁵]platinum(II) (3)

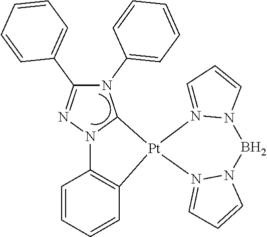

Synthesis analogous to the general synthesis procedure. 0.340 g (0.8 mmol) 1,3,4-triphenyl-1H-1,2,4-triazolium iodide⁴ and 0.093 g (0.4 mmol, 0.5 eq) silver(I) oxide are added to 20 ml DMF (T₁=55° C.). Subsequently, 0.299 g (0.8 mmol, 1 eq) Pt(COD)Cl₂ is added (T₂=115° C.). For the final step of the reaction, 0.298 g (1.6 mmol, 2 eq) potassium dihydrobis(pyrazol-1-yl)borate is added. Eluent mixture: iso-hexane/DCM (1:1). Yield: 161 mg (32%); melting point: 270° C.; molecular formula: C₂₆H₂₂BN₇Pt; molar mass: 638.4 g/mol. 1H NMR in CD₂Cl₂ (600 MHz): δ=7.76 (dd, J=2.2, 0.7 HZ, 1H, CHₐᵣₒₘ), 7.59 (dd, J=2.3, 0.8 Hz, 1H, CHₐᵣₒₘ), 7.51-7.47 (m, 1H, CHₐᵣₒₘ), 7.47-7.41 (m, 2H, CHₐᵣₒₘ), 7.39 (dd, J=7.5, 1.2 Hz, 1H, CHₐᵣₒₘ), 7.35-7.31 (m, 2H, CHₐᵣₒₘ), 7.31-7.28 (m, 3H, CHₐᵣₒₘ), 7.26-7.15 (m, 3H, CHₐᵣₒₘ), 7.11-6.97 (m, 3H, CHₐᵣₒₘ), 6.44 (dd, J=2.1, 0.7 Hz, 1H, CHₐᵣₒₘ), 6.28 (t, J=2.2 Hz, 1H, CHₐᵣₒₘ), 5.47 (t, J=2.2 Hz, 1H, CHₐᵣₒₘ). ¹³C NMR in CD₂Cl₂ (151 MHz): δ=161.0 (Cᵢ), 152.9 (Cᵢ), 146.6 (Cᵢ), 141.7 (CHₐᵣₒₘ), 141.1 (CHₐᵣₒₘ), 136.5 (CHₐᵣₒₘ), 135.3 (Cᵢ), 134.9 (CHₐᵣₒₘ), 134.8 (CHₐᵣₒₘ), 131.1 (CHₐᵣₒₘ), 130.3 (CHₐᵣₒₘ), 129.7 (CHₐᵣₒₘ), 129.1 (CHₐᵣₒₘ), 127.6 (Cᵢ), 126.2 (CHₐᵣₒₘ), 125.6 (Cᵢ), 124.8 (CHₐᵣₒₘ), 112.9 (CHₐᵣₒₘ), 105.7 (CHₐᵣₒₘ), 105.6 (CHₐᵣₒₘ). ¹⁹⁵Pt NMR in CD₂Cl₂ (129 MHz): δ=−3837.2 (s). MS (ESI): m/z=637.4 [M+H]⁺, 1294.5 [2M+NH₄]⁺. Elemental analysis: calculated C, 48.92%; H, 3.47%; N, 15.38%; found C, 48.67%; H, 3.44%; N, 15.24%.

### [Dihydrobis(pyrazol-1-yl-κN²)borate][1-methyl-3-(phenyl-κC²)-1H-imidazo[4,5-b]pyridin-2-ylidene-κC²]platinum(II) (K)

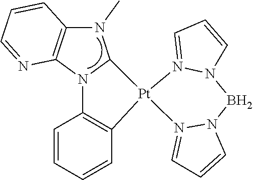

Synthesis analogous to the general synthesis procedure. 0.270 g (0.8 mmol) 1-methyl-3-phenyl-1H-imidazo[4,5-b]pyridinium iodide⁵ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.298 g (1.6 mmol, 2 eq) potassium dihydrobis(pyrazol-1-yl)borate is added. Eluent mixture: iso-hexane/DCM (2:5). Yield: 124 mg (28%); melting point: 244° C.; molecular formula: C₁₉H₁₈BN₇Pt; molar mass: 550.29 g/mol. 1H NMR in CDCl₃ (600 MHz): δ=8.52 (dd, J=4.9, 1.4 HZ, 1H, CHₐᵣₒₘ), 8.50 (dd, J=7.8, 1.3 Hz, 1H, CHₐᵣₒₘ), 7.79 (d, J=1.4 HZ, 1H, CHₐᵣₒₘ), 7.70 (d, J=2.0 HZ, 1H, CHₐᵣₒₘ), 7.69 (d, J=2.3 Hz, 1H, CHₐᵣₒₘ), 7.67 (dd, J=8.0, 1.4 Hz, 1H, CHₐᵣₒₘ), 7.64 (d, J=1.6 Hz, 1H, CHₐᵣₒₘ), 7.43 (dd, J=7.5, 1.4 Hz, 1H, CHₐᵣₒₘ), 7.31 (dd, J=8.0, 4.9 Hz, 1H, CHₐᵣₒₘ), 7.23 (td, J=7.6, 1.4 Hz, 1H, CHₐᵣₒₘ), 7.06 (td, J=7.4, 1.4 Hz, 1H, CHₐᵣₒₘ), 6.29 (t, J=2.2 Hz, 1H, CHₐᵣₒₘ), 6.24 (t, J=2.2 Hz, 1H, CHₐᵣₒₘ), 3.75 (s, 3H, NCH3). ¹³C NMR in CDCl₃ (151 MHz): δ=171.5 (Cᵢ), 148.0 (Cᵢ), 145.4 (Cᵢ), 145.3 (CHₐᵣₒₘ), 142.0 (CHₐᵣₒₘ), 141.6 (CHₐᵣₒₘ), 136.4 (CHₐᵣₒₘ), 136.4 (CHₐᵣₒₘ), 134.7 (CHₐᵣₒₘ), 129.3 (Cᵢ), 128.3 (Cᵢ), 124.7 (CHₐᵣₒₘ), 124.6 (CHₐᵣₒₘ), 118.6 (CHₐᵣₒₘ), 118.0 (CHₐᵣₒₘ), 114.7 (CHₐᵣₒₘ), 105.5 (CHₐᵣₒₘ), 105.2 (CHₐᵣₒₘ), 34.8 (NCH₃). ¹⁹⁵Pt NMR in CDCl₃ (64 MHz): δ=−3748.6 (s). MS (ESI): m/z=551.3 [M+H]⁺. Elemental analysis: calculated C, 41.47%; H, 3.30%; N, 17.82%; found C, 41.11%; H, 3.32%; N, 17.52%.

### [Dihydrobis(3,5-dimethylpyrazol-1-yl-κN²)borate][1-methyl-3-(phenyl-κC²)_1H-imidazo[4,5-b]pyridin-2-ylidene-κC²]platinum(II) (L)

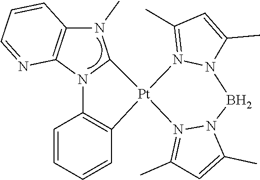

Synthesis analogous to the general synthesis procedure. 0.270 g (0.8 mmol) 1-methyl-3-phenyl-1H-imidazo[4,5-b]pyridinium iodide⁵ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent mixture: iso-hexane/DCM (1:1). Yield: 99 mg (20%); melting point: 257° C.; molecular formula: C₂₃H₂₆BN₇Pt; molar mass: 606.40 g/mol. ¹H NMR in CDCl₃ (600 MHz): δ=8.49 (dd, J=4.9, 1.4 Hz, 1H, CHₐᵣₒₘ), 8.43 (dd, J=7.8, 1.3 Hz, 1H, CHₐᵣₒₘ), 7.63 (dd, J=8.1, 1.4 Hz, 1H, CHₐᵣₒₘ), 7.39-7.28 (m, 1H, CHₐᵣₒₘ), 7.29-7.26 (m, 1H, CHₐᵣₒₘ), 7.17 (td, J=7.6, 1.4 Hz, 1H, CHₐᵣₒₘ), 6.96 (td, J=7.4, 1.3 Hz, 1H, CHₐᵣₒₘ), 5.82 (s, 1H, CHₐᵣₒₘ), 5.79 (s, 1H, CHₐᵣₒₘ), 3.69 (s, 3H, NCH3), 2.34 (s, 6H, CCH₃), 2.29 (s, 3H, CCH₃), 2.25 (s, 3H, CCH₃). ¹³C NMR in CDCl₃ (151 MHz): δ=171.8 (Cᵢ), 148.0 (Cᵢ), 147.9 (Cᵢ), 147.8 (Cᵢ), 145.5 (Cᵢ), 145.2 (Cᵢ), 145.1 (CHₐᵣₒₘ), 136.4 (CHₐᵣₒₘ), 129.7 (Cᵢ), 128.3 (Cᵢ), 124.3 (CHₐᵣₒₘ), 124.1 (CHₐᵣₒₘ), 118.3 (CHₐᵣₒₘ), 117.8 (CHₐᵣₒₘ), 114.2 (CHₐᵣₒₘ), 105.9 (CHₐᵣₒₘ), 105.3 (CHₐᵣₒₘ), 33.0 (NCH₃), 15.5 (CCH₃), 14.5 (CCH₃), 12.9 (CCH₃), 12.9 (CCH₃). ¹⁹⁵Pt NMR in CDCl₃ (129 MHz): δ=−3749.8 (s). MS (ESI): m/z=607.5 [M+H]⁺, 624.4 [M+NH₄]⁺. Elemental analysis: calculated C, 45.56%; H, 4.32%; N, 16.17%; found C, 45.19%; H, 4.24%; N, 16.02%.

### [Cycloocta-1,5-diylbis(4-methylpyrazol-1-yl-κN²)borate][1-methyl-3-(phenyl-κC²)-1/imidazo[4,5-b]pyridin-2-ylidene-κC²]platinum(II) (M)

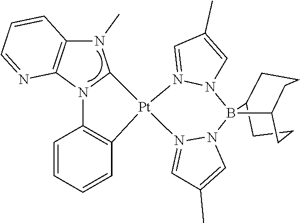

Synthesis analogous to the general synthesis procedure. 0.270 g (0.8 mmol) 1-methyl-3-phenyl-1H-imidazo[4,5-b]pyridinium iodide⁵ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.516 g (1.6 mmol, 2 eq) potassium cycloocta-1,5-diylbis(4-methylpyrazol-1-yl)borate is added. Eluent mixture: iso-hexane/DCM (3:5). Yield: 82 mg (15%); decomposition point>310° C.; molecular formula: C₂₉H₃₄BN₇Pt; molar mass: 686.53 g/mol. 1H NMR in CDCl₃ (600 MHz): δ=8.50 (dd, J=4.9, 1.4 Hz, 1H, CHₐᵣₒₘ), 8.47 (dd, J=7.8, 1.3 Hz, 1H, CHₐᵣₒₘ), 7.66 (dd, J=8.0, 1.4 Hz, 1H, CHₐᵣₒₘ), 7.57 (s, 1H, CHₐᵣₒₘ), 7.55 (s, 1H, CHₐᵣₒₘ), 7.54 (s, 1H, CHₐᵣₒₘ), 7.52 (dd, J=7.5, 1.3 Hz, 1H, CHₐᵣₒₘ), 7.49 (s, 1H, CHₐᵣₒₘ), 7.29 (dd, J=8.0, 4.9 Hz, 1H, CHₐᵣₒₘ), 7.23 (td, J=7.6, 1.4 Hz, 1H, CHₐᵣₒₘ), 7.06 (td, J=7.4, 1.4 Hz, 1H, CHₐᵣₒₘ), 3.89 (s, 3H, NCH₃), 3.54 (bs, 1H, CH_{9-BBN}), 2.31-2.22 (m, 2H, C/2, 9-BBN), 2.08 (s, 3H, CCH₃), 2.04 (s, 3H, CCH₃), 2.02-1.85 (m, 4H, CH_{2, 9-BBN}), 1.76-1.60 (m, 2H, CH_{2, 9-BBN}), 1.60-1.47 (m, 4H, CH_{2, 9-BBN}), 1.39 (s, 1H, CH_{9-BBN}). ¹³C NMR in CDCl₃ (151 MHz): δ=172.3 (Cᵢ), 147.7 (Cᵢ), 145.5 (Cᵢ), 145.0 (CHₐᵣₒₘ), 141.2 (CHₐᵣₒₘ), 141.1 (CHₐᵣₒₘ), 134.3 (CHₐᵣₒₘ), 133.9 (CHₐᵣₒₘ), 133.7 (CHₐᵣₒₘ), 129.9 (Cᵢ), 128.3 (Cᵢ), 124.6 (CHₐᵣₒₘ), 124.2 (CHₐᵣₒₘ), 118.3 (CHₐᵣₒₘ), 117.8 (CHₐᵣₒₘ), 115.3 (Cᵢ), 114.8 (Cᵢ), 114.6 (CHₐᵣₒₘ), 34.7 (NCH₃), 32.6 (CH_{2, 9-BBN}), 32.3 (CH_{2, 9-BBN}), 31.4 (CH_{2, 9-BBN}), 30.4 (CH_{2, 9-BBN}), 24.8 (CH_{2, 9-BBN}), 24.7 (CH_{2, 9-BBN}), 9.3 (CCH₃), 9.2 (CCH₃). ¹⁹⁵Pt NMR in CDCl₃ (129 MHz): δ=−3636.7 (s). MS (ESI): m/z=687.4 [M+H]⁺. Elemental analysis: calculated C, 50.74%; H, 4.99%; N, 14.28%; found C, 50.92%; H, 5.24%; N, 13.96%.

### [Dihydrobis(pyrazol-1-yl-κN²][3-(4-fluorophenyl-κC²)-1-methyl-1,2,3-triazol-4-ylidene-κC⁴]platinum(II) (N)

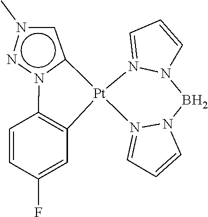

Synthesis analogous to the general synthesis procedure. 0.244 g (0.8 mmol) 1-(4-fluorophenyl)-3-methyl-1H-1,2,3-triazolium iodide⁶ and 0.093 g (0.4 mmol, 0.5 eq) silver(I) oxide are added to 20 ml DMF (T₁=85° C.). Subsequently, 0.299 g (0.8 mmol, 1 eq) Pt(COD)Cl₂ is added (T₂=115° C.). For the last step of the reaction, 0.262 g (1.41 mmol, 1.76 eq) potassium dihydrobis(pyrazol-1-yl)borate is added, deviating from the general prescription. Eluent: DCM. Yield: 114 mg (28%); melting point: 219° C.; molecular formula: C₁₅H₁₅BFN₇Pt; molar mass: 518.22 g/mol. ¹H NMR in DMSO-d₆ (600 MHz): δ=8.19 (s, 1H, CHₐᵣₒₘ), 7.87 (dd, J=2.1, 0.7 Hz, 1H, CHₐᵣₒₘ), 7.86 (dd, J=2.1, 0.7 Hz, 1H, CHₐᵣₒₘ), 7.80 (dd, J=2.3, 0.7 Hz, 1H, CHₐᵣₒₘ), 7.75 (dd, J=2.3, 0.7 Hz, 1H, CHₐᵣₒₘ), 7.56 (dd, J=8.6, 5.0 Hz, 1H, CHₐᵣₒₘ), 7.06 (dd, J=9.8, 2.7 Hz, 1H, CHₐᵣₒₘ), 7.00 (td, J=8.6, 2.7 Hz, 1H, CHₐᵣₒₘ), 6.43 (t, J=2.2 Hz, 1H, CHₐᵣₒₘ), 6.39 (t, J=2.2 Hz, 1H, CHₐᵣₒₘ), 4.25 (s, 3H, NCH₃), 3.57 (bs, 2H, BH₂). ¹³C NMR in DMSO-d₆ (151 MHz): δ=161.0 (d, J=246.9 Hz, Cᵢ), 142.0 (Cᵢ), 141.4 (CHₐᵣₒₘ), 141.1 (CHₐᵣₒₘ, Cᵢ), 136.1 (CHₐᵣₒₘ), 135.6 (CHₐᵣₒₘ), 134.9 (d, J=5.7 Hz, Cᵢ), 131.6 (CHₐᵣₒₘ), 120.7 (d, J=19.8 Hz, CHₐᵣₒₘ), 114.7 (d, J=9.1 Hz, CHₐᵣₒₘ), 110.0 (d, J=24.4 Hz, CHₐᵣₒₘ), 105.8 (CHₐᵣₒₘ), 105.6 (CHₐᵣₒₘ), 38.6 (NCH₃). ¹⁹F NMR in DMSO-d₆ (282 MHz): δ=−113.7 (s). MS: (ESI, m/z)=517.3 (M−H)⁺, 1035.4 (2M−H)⁺. Elemental analysis: calculated C, 34.77%; H, 2.92%; N, 18.92%; found C, 34.51%; H, 2.79%; N, 18.74%.

### [Dihydrobis(3,5-dimethylpyrazol-1-yl-κN²)borate][3-(4-fluorophenyl-κC²)-1-methyl-1,2,3-triazol-4-ylidene-κC⁴]platinum(II) (O)

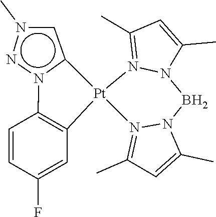

Synthesis analogous to the general synthesis procedure. 0.244 g (0.8 mmol) 1-(4-fluorophenyl)-3-methyl-1H-1,2,3-triazolium iodide⁶ and 0.093 g (0.4 mmol, 0.5 eq) silver(I) oxide are added to 20 ml DMF (T₁=85° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent: DCM. Yield: 74 mg (16%); melting point: 264° C.; molecular formula: C₁₉H₂₃BFN₇Pt; molar mass: 574.33 g/mol. 1H NMR in CDCl₃ (600 MHz): δ=7.42 (dd, J=8.6, 4.9 HZ, 1H, CHₐᵣₒₘ), 7.27 (s, 1H, CHₐᵣₒₘ), 7.15 6.96 (m, 1H, CHₐᵣₒₘ), 6.79 (td, J=8.5, 2.7 Hz, 1H, CHₐᵣₒₘ), 5.85 (s, 1H, CHₐᵣₒₘ), 5.77 (s, 1H, CHₐᵣₒₘ), 4.08 (s, 3H, NCH₃), 2.34 (s, 3H, CCH₃), 2.32 (s, 3H, CCH₃), 2.30 (s, 3H, CCH₃), 2.28 (s, 3H, CCH₃). ¹³C NMR in CDCl₃ (151 MHz): δ=162.24 (d, J=248.6 Hz, Cᵢ), 147.4 (Cᵢ), 147.3 (Cᵢ), 144.8 (Cᵢ), 144.7 (Cᵢ), 143.4 (Cᵢ), 142.01 (d, J=1.9 Hz, G), 134.9 (d, J=6.0 Hz, G), 131.6 (CHₐᵣₒₘ), 123.46 (d, J=19.9 Hz, CHₐᵣₒₘ), 114.61 (d, J=9.2 Hz, CHₐᵣₒₘ), 109.89 (d, J=25.0 Hz, CHₐᵣₒₘ), 105.8 (CHₐᵣₒₘ), 105.0 (CHₐᵣₒₘ), 38.5 (NCH₃), 15.0 (CCH₃), 14.7 (CCH₃), 13.0 (2CCH₃). ¹⁹F NMR in CDCl₃ (282 MHz): δ=−113.8 (s). ¹⁹⁵Pt NMR in CDCl₃ (129 MHz): δ=−3851.0 (s). MS (ESI): m/z=575.4 [M−H]⁺. Elemental analysis: calculated C, 39.73%; H, 4.04%; N, 17.07%; found C, 39.58%; H, 4.05%; N, 16.89%.

### [3-(2,4-difluorophenyl-κC⁶)-1-methyl-1,2,3-triazol-4-ylidene-κC⁴][dihydrobis(pyrazol-1-yl-κN²)borate]platinum(II) (P)

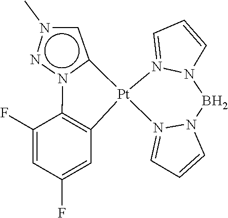

Synthesis analogous to the general synthesis procedure. 0.258 g (0.8 mmol) 1-(2,4-difluorophenyl)-3-methyl-1H-1,2,3-triazolium iodide and 0.093 g (0.4 mmol, 0.5 eq) silver(I) oxide are added to 20 ml DMF (T₁=85° C.). Subsequently, 0.299 g (0.8 mmol, 1 eq) Pt(COD)Cl₂ is added (T₂=115° C.). For the final step of the reaction, 0.298 g (1.6 mmol, 2 eq) potassium dihydrobis(pyrazol-1-yl)borate is added. Eluent mixture: iso-hexane/DCM (1:5). Yield: 153 mg (36%); melting point: 286° C.; molecular formula: C₁₅H₁₄BF₂N₇Pt; molar mass: 536.21 g/mol. 1H NMR in DMSO-d₆ (600 MHz): δ=8.22 (s, 1H), 7.87 (dd, J=2.1, 0.7 Hz, 1H), 7.86 (dd, J=2.1, 0.7 Hz, 1H), 7.81 (dd, J=2.3, 0.7 Hz, 1H), 7.76 (dd, J=2.3, 0.7 Hz, 1H), 7.14 (ddd, J=11.4, 9.1, 2.5 Hz, 1H), 6.91 (dd, J=9, 0, 2.5 Hz, 1H), 6.43 (t, J=2.2 Hz, 1H), 6.40 (t, J=2.2 Hz, 1H), 4.27 (s, 3H). ¹³C NMR in DMSO-d₆ (151 MHz): δ=160.7 (dd, J=250.4, 9.7 Hz, Cᵢ), 150.2 (dd, J=258.0, 13.4 Hz, Cᵢ), 141.8 (Cᵢ), 141.4 (CHₐᵣₒₘ), 141.1 (CHₐᵣₒₘ), 137.1 (Cᵢ), 136.2 (CHₐᵣₒₘ), 135.8 (CHₐᵣₒₘ), 131.0 (CHₐᵣₒₘ), 128.9 (Cᵢ), 116.7 (d, J=19.1 Hz, CHₐᵣₒₘ), 105.9 (CHₐᵣₒₘ), 105.7 (CHₐᵣₒₘ), 99.8 (dd, J=28.0, 22.8 Hz, CHₐᵣₒₘ), 38.8 (NCH₃). ¹⁹F NMR in DMSO-d₆ (282 MHz): δ=−108.5-−112.1 (m), −120.1-−123.1 (m). ¹⁹⁵Pt NMR in DMSO-d₆ (64 MHz): δ=−3829.4 (s). MS (ESI): m/z=535.2 (M−H)+. Elemental analysis: calculated C, 33.60%; H, 2.63%; N, 18.29%; found C, 34.00%; H, 2.50%; N, 17.93%.

### [3-(2,4-difluorophenyl-κC⁶)-1-methyl-1,2,3-triazol-4-ylidene-κC⁴][dihydrobis(3,5-dimethylpyrazol-1-yl-κN²)borate]platinum(II) (Q)

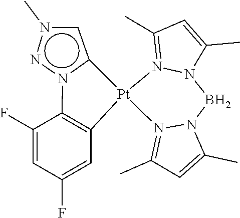

Synthesis analogous to the general synthesis procedure. 0.258 g (0.8 mmol) 1-(2,4-difluorophenyl)-3-methyl-1H-1,2,3-triazolium iodide and 0.093 g (0.4 mmol, 0.5 eq) silver(I) oxide are added to 20 ml DMF (T₁=85° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent mixture: iso-hexane/DCM (2:5).

Yield: 83 mg (18%); melting point: 235° C.; molecular formula: C₁₉H₂₂BF₂N₇Pt; molar mass: 592.32 g/mol. 1H NMR in DMSO-d₆ (600 MHz): δ=8.05 (s, 1H, CHₐᵣₒₘ), 7.08 (ddd, J=11.4, 9.1, 2.5 Hz, 1H, CHₐᵣₒₘ), 6.64 (dd, J=8.8, 2.5 Hz, 1H, CHₐᵣₒₘ), 5.96 (s, 1H, CHₐᵣₒₘ), 5.90 (s, 1H, CHₐᵣₒₘ), 4.24 (s, 3H, NCH₃), 2.28 (s, 3H, CCH₃), 2.25 (s, 3H, CCH₃), 2.22 (s, 3H, CCH₃), 2.21 (s, 3H, CCH3). ¹³C NMR in DMSO-d₆ (151 MHz): δ=160.6 (dd, J=249.8, 9.7 Hz, Cᵢ), 150.0 (dd, J=257.8, 13.3 Hz, Cᵢ), 147.6 (Cᵢ), 146.4 (Cᵢ), 144.0 (2Cᵢ), 141.6 (Cᵢ), 137.2 (d, J=6.5 Hz, Cᵢ), 132.4 (CHₐᵣₒₘ), 128.8 (dd, J=4.6, 2.8 Hz, C), 117.7 (d, J=18.9 Hz, CHₐᵣₒₘ), 105.8 (CHₐᵣₒₘ), 105.1 (CHₐᵣₒₘ), 99.41 (dd, J=28.1, 22.7 Hz, CHₐᵣₒₘ), 38.7 (NCH₃), 14.6 (CCH₃), 14.3 (CCH₃), 12.5 (CCH₃), 12.4 (CCH₃). ¹⁹F NMR in DMSO-d₆ (282 MHz): δ=−111.84 (d, J=5.9 Hz, CF), −122.86 (d, J=5.8 Hz, CF). ¹⁹⁵Pt NMR in DMSO-d₆ (129 MHz): δ=−3844.3 (s). MS (ESI): m/z=591.2 [M−H]⁺. Elemental analysis: calculated C, 38.53%; H, 3.74%; N, 16.55%; found C, 38.20%; H, 3.64%; N, 16.16%.

### [dihydrobis(3,5-dimethylpyrazol-1-yl-κN²)borate][1-methyl-3-(phenyl-κC²)-1/imidazolin-2-ylidene-κC²]platinum(II) R

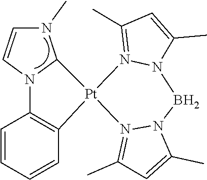

Synthesis analogous to the general synthesis procedure. 0.229 g (0.8 mmol) 1-methyl-3-phenyl-1H-imidazolium iodide⁷ and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent mixture: iso-hexane/DCM (3:5). Yield: 79 mg (18%); melting point: 243° C. (dec.); molecular formula: C₂₀H₂₅BN₆Pt; molar mass: 555.35 g/mol. 1H NMR in CDCl₃ (600 MHz): δ=7.27 (d, J=2.1 Hz, 1H, CHₐᵣₒₘ), 7.27 7.24 (m, 1H, CHₐᵣₒₘ), 7.03 (td, J=7.5, 1.3 Hz, 1H, CHₐᵣₒₘ), 6.97 (dd, J=7.8, 1.3 Hz, 1H, CHₐᵣₒₘ), 6.88 (td, J=7.4, 1.3 HZ, 1H, CHₐᵣₒₘ), 6.80 (d, J=2.1 Hz, 1H, CHₐᵣₒₘ), 5.79 (s, 1H, CHₐᵣₒₘ), 5.74 (s, 1H, CHₐᵣₒₘ), 3.52 (s, 3H), 2.32 (s, 3H, CCH₃), 2.31 (s, 3H, CCH₃), 2.26 (s, 3H, CCH₃), 2.25 (s, 3H, CCH₃). ¹³C NMR in CDCl₃ (151 MHz): δ=158.5 (f), 147.7 (Cᵢ), 147.6 (Cᵢ), 147.5 (Cᵢ), 145.2 (Cᵢ), 144.8 (Cᵢ), 137.0 (CHₐᵣₒₘ), 129.9 (Cᵢ), 124.4 (CHₐᵣₒₘ), 123.5 (CHₐᵣₒₘ), 121.2 (CHₐᵣₒₘ), 115.1 (CHₐᵣₒₘ), 110.1 (CHₐᵣₒₘ), 105.6 (CHₐᵣₒₘ), 105.1 (CHₐᵣₒₘ), 35.8 (NCH₃), 15.3 (CCH₃), 14.6 (CCH₃), 13.0 (CCH₃), 12.9 (CCH₃). ¹⁹⁵Pt NMR in CDCl₃ (64 MHz): δ=−3864.2 (s). MS (ESI): m/z=556.4 [M+H]⁺, 1128.7 [2M+NH₄]⁺. Elemental analysis: calculated C, 43.25%; H, 4.54%; N, 15.13%; found C, 42.95%; H, 4.36%; N, 14.82%.

### [Dihydrobis(3,5-dimethylpyrazol-1-yl-κN²)borate][1-methyl-3-(5-methylphenyl-κC²)-1H-imidazolin-2-ylidene-κC²]platinum(II) (S)

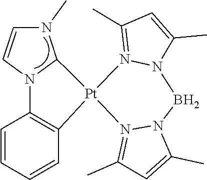

Synthesis analogous to the general synthesis procedure. 0.240 g (0.8 mmol) 1-methyl-3-(3-methylphenyl)-1H-imidazolium iodide and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent mixture: iso-hexane/DCM (3:5). Yield: 147 mg (33%); melting point: 227° C.; molecular formula: C₂₁H₂₇BN₆Pt; molar mass: 569.38 g/mol. 1H NMR in CDCl₃ (300 MHz): δ=7.25 (d, J=2.1 Hz, 1H, CHₐᵣₒₘ), 7.23-7.00 (m, 1H, CHₐᵣₒₘ), 6.84-6.74 (m, 2H, CHₐᵣₒₘ), 6.75-6.67 (m, 1H, CHₐᵣₒₘ), 5.78 (s, 1H, CHₐᵣₒₘ), 5.74 (s, 1H, CHₐᵣₒₘ), 3.50 (s, 3H, NCH₃), 2.32 (s, 3H, CCH₃), 2.31 (s, 3H, CCH₃), 2.28 (s, 3H, CCH₃), 2.25 (s, 3H, CCH₃), 2.25 (s, 3H, CCH₃). ¹³C NMR in CDCl₃ (75 MHz): δ=158.7 (Cᵢ), 147.7 (Cᵢ), 147.6 (2 Cᵢ), 145.2 (Cᵢ), 144.8 (Cᵢ), 136.8 (CHₐᵣₒₘ), 133.1 (Cᵢ), 125.8 (Cᵢ), 125.0 (CHₐᵣₒₘ), 121.0 (CHₐᵣₒₘ), 115.0 (CHₐᵣₒₘ), 111.2 (CHₐᵣₒₘ), 105.5 (CHₐᵣₒₘ), 105.0 (CHₐᵣₒₘ), 35.8 (NCH₃), 21.4 (CCH₃), 15.3 (CCH₃), 14.6 (CCH₃), 13.0 (CCH₃), 12.9 (CCH₃) ¹⁹⁵Pt NMR in CDCl₃ (64 MHz): δ=−3871.3 (s). MS (ESI): m/z=570.5 [M+H]⁺, 1156.5 [2M+NH₄]⁺. Elemental analysis: calculated C, 44.30%; H, 4.78%; N, 14.76%; found C, 44.46%; H, 4.66%; N, 14.56%.

### [Dihydrobis(3,5-dimethylpyrazol-1-yl-κN²)borate][1-(phenyl-κC²)-3-(2,4,6-trimethylphenyl)-1H-imidazolin-2-ylidene-κC²]platinum(II) (T)

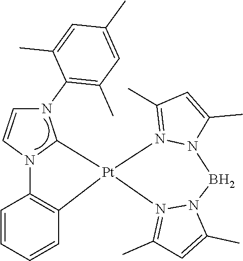

Synthesis analogous to the general synthesis procedure. 0.280 g (0.8 mmol) 1-phenyl-3-(2,4,6-trimethyphenyl)-1H-imidazolium tetrafluoroborate8 and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.387 g (1.6 mmol, 2 eq) potassium dihydrobis(3,5-dimethylpyrazol-1-yl)borate is added. Eluent mixture: iso-hexane/DCM (3:5). Yield: 84 mg (16%); melting point: 245° C.; molecular formula: C₂₈H₃₃BN₆Pt; molar mass: 659.50 g/mol. 1H NMR in CDCl₃ (300 MHz): δ=7.46 (d, J=2.1 Hz, 1H, CHₐᵣₒₘ), 7.42-7.17 (m, 1H, CHₐᵣₒₘ), 7.09 (d, J=3.8 Hz, 2H, CHₐᵣₒₘ), 7.01-6.86 (m, 1H, CHₐᵣₒₘ), 6.85-6.73 (m, 2H, CHₐᵣₒₘ), 6.46 (s, 1H, CHₐᵣₒₘ), 5.73 (s, 1H, CH_{Pz}), 5.11 (s, 1H, CH_{Pz}), 2.27 (s, 3H, CCH₃), 2.24 (s, 6H, CCH₃), 2.22 (s, 3H, CCH₃), 2.19 (s, 3H, CCH₃), 2.19 (s, 3H, CCH₃), 1.67 (s, 3H, CCH₃). ¹³C NMR in CDCl₃ (75 MHz): δ=157.7 (Cᵢ), 147.6 (Cᵢ), 147.3 (Cᵢ), 146.9 (Cᵢ), 144.5 (Cᵢ), 144.3 (Cᵢ), 138.7 (Cᵢ), 136.9 (CHₐᵣₒₘ), 136.5 (Cᵢ), 134.3 (Cᵢ), 133.3 (Cᵢ), 130.3 (Cᵢ), 129.0 (CHₐᵣₒₘ), 128.3 (CHₐᵣₒₘ), 124.9 (CHₐᵣₒₘ), 123.6 (CHₐᵣₒₘ), 122.0 (CHₐᵣₒₘ), 114.7 (CHₐᵣₒₘ), 110.4 (CHₐᵣₒₘ), 105.4 (CHₐᵣₒₘ), 103.7 (CHₐᵣₒₘ), 20.9 (CCH₃), 19.0 (CCH₃), 18.9 (CCH₃), 15.5 (CCH₃), 15.0 (CCH₃), 13.0 (CCH₃), 12.6 (CCH₃). ¹⁹⁵Pt NMR in CDCl₃ (64 MHz): δ=−3859.5 (s). MS (ESI): m/z=660.5 [M+H]⁺. Elemental analysis: calculated C, 50.99%; H, 5.04%; N, 12.74%; found C, 51.35%; H, 5.21%; N, 12.52%.

### [cycloocta-1,5-diylbis(pyrazol-1-yl-κN²)borate][1-(phenyl-κC²)-3-(2,4,6-trimethylphenyl)-1/imidazolin-2-ylidene-κC²]platinum(II) (U)

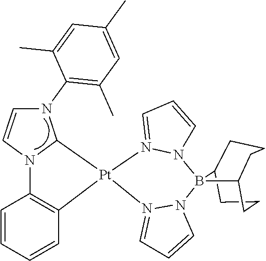

Synthesis analogous to the general synthesis procedure. 0.280 g (0.8 mmol) 1-phenyl-3-(2,4,6-trimethyphenyl)-1H-imidazolium tetrafluoroborate8 and 0.093 g (0.4 mmol, 0.5 eq) silver(I) oxide are added to 20 ml DMF (T₁=45° C.). Subsequently, 0.299 g (0.8 mmol, 1 eq) Pt(COD)Cl₂ is added (T₂=115° C.). For the final step of the reaction, 0.516 g (1.6 mmol, 2 eq) potassium cycloocta-1,5-diylbis(4-methylpyrazol-1-yl)borate is added. Eluent mixture: iso-hexane/DCM (5:3). Yield: 245 mg (43%); melting point: 268° C.; molecular formula: C₃₂H₃₇BN₆Pt; molar mass: 711.58 g/mol. 1H NMR in CDCl₃ (600 MHz): δ=7.69 (d, J=2.1 Hz, 1H, CHₐᵣₒₘ), 7.68 (d, J=2.4 HZ, 1H, CHₐᵣₒₘ), 7.53 (d, J=2.1 HZ, 1H, CHₐᵣₒₘ), 7.51-7.41 (m, 2H, CHₐᵣₒₘ), 7.18-7.11 (m, 2H, CHₐᵣₒₘ), 7.03-6.98 (m, 1H, CHₐᵣₒₘ), 6.96 (s, 1H, CHₐᵣₒₘ), 6.81 (d, J=2.1 Hz, 1H, CHₐᵣₒₘ), 6.65 (d, J=2.0 Hz, 1H, CHₐᵣₒₘ), 6.45 (d, J=2.1 Hz, 1H, CHₐᵣₒₘ), 6.16 (t, J=2.2 Hz, 1H, CHₐᵣₒₘ), 5.54 (t, J=2.2 Hz, 1H, CHₐᵣₒₘ), 3.37 (bs, 1H, CH_{9-BBN}), 2.31 (s, 3H, CCH₃), 2.25 (s, 3H, CCH₃), 2.24-2.13 (m, 2H, CH_{2, 9-BBN}), 2.08 (s, 3H, CCH₃), 2.02-1.88 (m, 2H, CH_{9-BBN}), 1.88-1.79 (in, 2H, CH_{2, 9-BBN}), 1.66-1.56 (m, 2H, CH_{2, 9-BBN}), 1.53-1.35 (m, 4H, CH_{2, 9-BBN}), 1.32-1.29 (bs, 1H, CH_{9-BBN}). ¹³C NMR in CDCl₃ (151 MHz): δ=156.6 (Cᵢ), 146.6 (Cᵢ), 141.0 (CHₐᵣₒₘ), 141.0 (Cᵢ), 139.5 (Cᵢ), 136.4 (Cᵢ), 135.1 (CHₐᵣₒₘ), 134.9 (Cᵢ), 134.3 (CHₐᵣₒₘ), 133.6 (CHₐᵣₒₘ), 133.0 (CHₐᵣₒₘ), 129.8 (Cᵢ), 129.4 (CHₐᵣₒₘ), 128.8 (CHₐᵣₒₘ), 125.1 (CHₐᵣₒₘ), 123.7 (CHₐᵣₒₘ), 121.8 (CHₐᵣₒₘ), 114.9 (CHₐᵣₒₘ), 110.6 (CHₐᵣₒₘ), 104.5 (CHₐᵣₒₘ), 103.0 (CHₐᵣₒₘ), 32.8 (CCH₂), 32.6 (CCH₂), 31.5 (CCH₂), 30.2 (CCH₂), 26.4 (CH), 24.7 (CCH₂), 24.3 (CCH₂), 22.1 (CH), 21.0 (CCH₃), 18.7 (CCH₃), 18.1 (CCH₃). ¹⁹⁵Pt NMR in CDCl₃ (64 MHz): δ=−3736.1 (s). MS (ESI): m/z=712.5 [M+H]⁺. Elemental analysis: calculated C, 54.01%; H, 5.24%; N, 11.81%; found C, 54.39%; H, 5.43%; N, 11.54%.

### [Cycloocta-1,5-diylbis(4-methylpyrazol-1-yl-κN²)borate][1-(phenyl-κC²)-3-(2,4,6-trimethylphenyl)-1H-imidazolin-2-ylidene-κC²]platinum(II) (V)

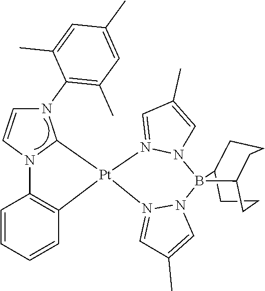

According to the general synthesis instruction, 280 mg (0.8 mmol) of 1-phenyl-3-(2,4,6-trimethylphenyl)-1H-imidazolium tetrafluoroborate8 and 93 mg (0.4 mmol, 0.5 eq) are added to 20 ml DMF. Following the synthesis procedure, 299 mg (0.8 mmol, 1 eq) of Pt(COD)Cl₂ is added. For the final step of the reaction, 516 mg (1.6 mmol, 2 eq) potassium cycloocta-1,5-diylbis(4-methylpyrazol-1-yl)borate is added. The product is then isolated by column chromatography with the eluent mixture iso-hexane/DCM (1:1). Yield: 326 mg (55%); melting point: 283° C.; molecular formula: C₃₄H₄₁BN₆Pt; molar mass: 739.63 g/mol. ¹H NMR in CDCl₃ (600 MHz): δ=7.52 (d, J=2.1 HZ, 1H, CHₐᵣₒₘ), 7.51-7.43 (m, 3H, CHₐᵣₒₘ), 7.23 (s, 1H, CHₐᵣₒₘ), 7.17-7.09 (m, 2H, CHₐᵣₒₘ), 7.01 (td, J=7.2, 1.8 Hz, 1H, CHₐᵣₒₘ), 6.99 (s, 1H, CHₐᵣₒₘ), 6.79 (d, J=2.1 HZ, 1H, CHₐᵣₒₘ), 6.68 (s, 1H, CHₐᵣₒₘ), 6.20 (s, 1H, CHₐᵣₒₘ), 3.27 (bs, 1H, CH_{9-BBN}), 2.30 (s, 3H, CCH₃), 2.28 (s, 3H, CCH₃), 2.26-2.13 (m, 2H, CH_{2, 9-BBN}), 2.06 (s, 3H, CCH₃), 2.02 (s, 3H, CCH₃), 1.99-1.85 (m, 2H, C/2, 9-BBN), 1.85-1.74 (m, 2H, CH_{2, 9-BBN}), 1.68 (s, 3H, CCH₃), 1.63-1.53 (m, 2H, CH_{2, 9-BBN}), 1.52-1.33 (m, 4H, CH_{2, 9-BBN}), 1.22 (bs, 1H, CH_{9-BBN}). ¹³C NMR in CDCl₃ (151 MHz): δ=157.0 (Cᵢ), 146.6 (Cᵢ), 141.0 (CHₐᵣₒₘ), 140.7 (CHₐᵣₒₘ), 139.3 (Cᵢ), 136.6 (Cᵢ), 135.2 (CHₐᵣₒₘ), 135.1 (Cᵢ), 134.5 (Cᵢ), 133.1 (CHₐᵣₒₘ), 132.3 (CHₐᵣₒₘ), 130.3 (Cᵢ), 129.4 (CHₐᵣₒₘ), 128.5 (CHₐᵣₒₘ), 125.0 (CHₐᵣₒₘ), 123.6 (CHₐᵣₒₘ), 121.7 (CHₐᵣₒₘ), 114.9 (CHₐᵣₒₘ), 114.5 (Cᵢ), 112.8 (Cᵢ), 110.5 (CHₐᵣₒₘ), 32.8 (CH2), 32.6 (CH₂), 31.5 (CH₂), 30.2 (CH₂), 24.8 (CH₂), 24.4 (CH₂), 21.2 (CCH₃), 18.7 (CCH₃), 18.1 (CCH₃), 9.2 (CCH₃), 8.8 (CCH₃). ¹⁹⁵Pt NMR in CDCl₃ (129 MHz): δ=−3726.2 (s). MS (ESI): m/z=740.5 [M+H]⁺. Elemental analysis: calculated C, 55.21%; H, 5.59%; N, 11.36%; found C, 55.41%; H, 5.60%; N, 11.38%.

Furthermore, the following compounds W, X and 3 to 12 were generated and measured:

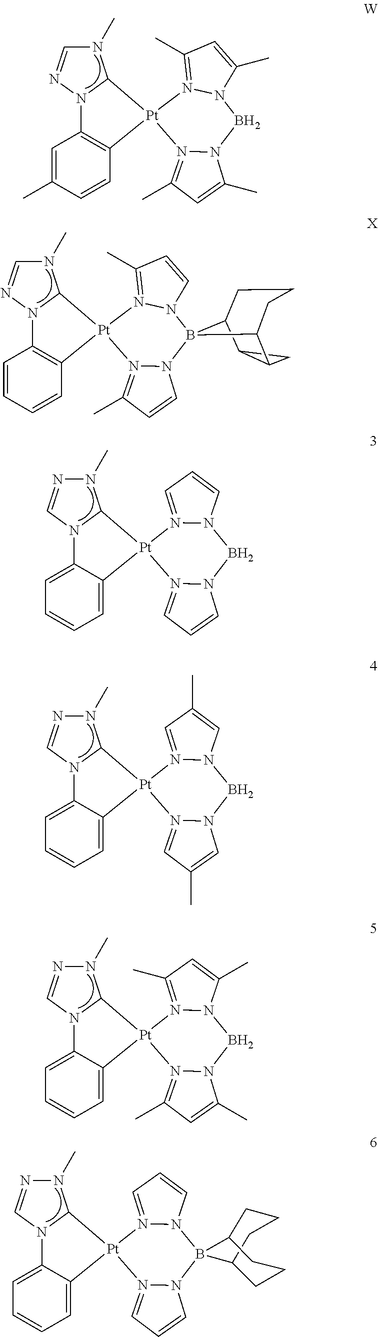

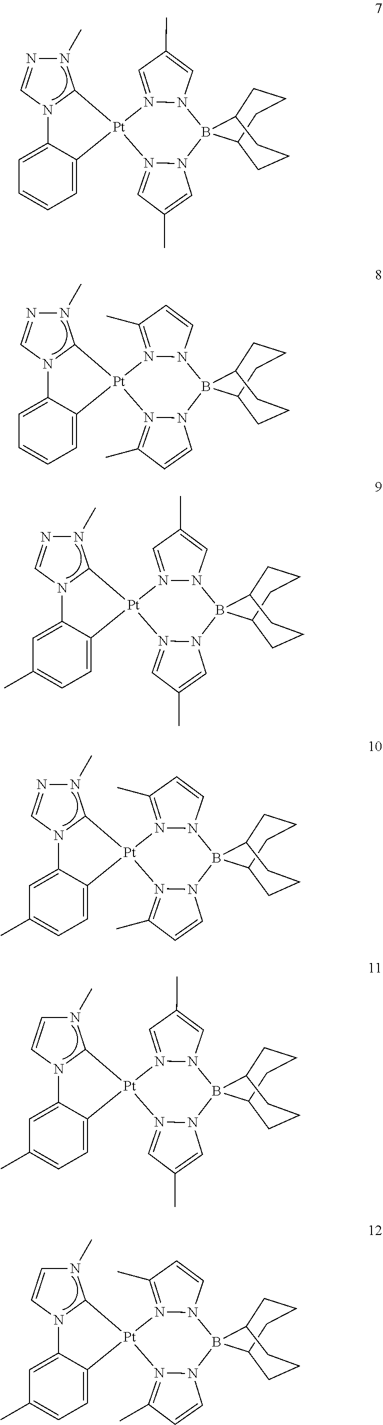

[Dihydrobis(3,5-dimethylpyrazol-1-yl-κN²)borate][4-methyl-1-(5-methylphenyl-κC²-1H-1,2,4-triazol-5-ylidene-κC⁵]platinum(II) (W): synthesis analogous to the general synthesis procedure. 0.301 g (0.8 mmol) 4-methyl-1-(5-methylphenyl)-1H-1,2,4-triazolium iodide and 0.093 g (0.4 mmol, 0.5 eq) silver(I) oxide are placed in 20 ml DMF (T₁=45° C.). Subsequently, 0.299 g (0.8 mmol, 1 eq) Pt(COD)Cl₂ is added (T₂=125° C.). For the final step of the reaction, 0.387 g (1.6 mmol, 2 eq) potassium dihydrobis(3,5-dimethylpyrazol-1-yl)borate is added. The product is isolated by column chromatography with an eluent mixture matched for polarity. Yield: 112 mg (25%); melting point: 265° C.; molecular formula: C₂₀H₂₆BN₇Pt; molar mass: 570.36 g/mol. 1H NMR in CDCl₃ (300 MHz) δ=7.83 (s, 1H, CHₐᵣₒₘ), 7.22-7.08 (M, 2H, CHₐᵣₒₘ), 6.88-6.71 (m, 1H, CHₐᵣₒₘ), 5.80 (s, 1H, CHₐᵣₒₘ), 5.76 (s, 1H, CHₐᵣₒₘ), 3.56 (s, 3H, NCH₃), 2.33-2.30 (m, 9H, CCH₃), 2.28 (s, 3H, CCH₃), 2.24 (s, 3H, CCH₃). ¹³C NMR in CDCl₃ (75 MHz) δ=161.4 (Cᵢ), 147.8 (Cᵢ), 147.7 (Cᵢ), 146.1 (Cᵢ), 145.5 (Cᵢ), 145.0 (Cᵢ), 141.9 (CHₐᵣₒₘ), 136.4 (CHₐᵣₒₘ), 133.8 (Cᵢ), 126.2 (CHₐᵣₒₘ), 122.5 (Cᵢ), 112.9 (CHₐᵣₒₘ), 105.7 (CHₐᵣₒₘ), 105.1 (CHₐᵣₒₘ), 33.3 (NCH₃), 21.3 (CCH₃), 15.4 (CCH₃), 14.8 (CCH₃), 13.0 (CCH₃), 12.9 (CCH3). ¹⁹⁵Pt NMR in CDCl₃ (64 MHz) δ=−3889.8 (s). MS (ESI): m/z=571.5 [M+H]⁺, 588.4 [M+NH₄]⁺, 1157.6 [2M+NH₄]⁺. Elemental analysis: calculated C, 42.12%; H, 4.59%; N, 17.19%; found C, 42.10%; H, 4.86%; 16.84%.

[Cycloocta-1,5-diylbis(3-methylpyrazol-1-yl-κN²)borate][4-methyl-1-(phenyl-κC²)-1H-1,2,4-triazol-5-ylidene-κC⁵]platinum(II) (X): synthesis analogous to the general synthesis procedure. 0.230 g (0.8 mmol) 4-methyl-1-phenyl-1H-1,2,4-triazolium iodide and 0.093 g (0.4 mmol, 0.5 eq) silver(I) oxide are placed in 20 ml DMF (T₁=45° C.). Subsequently, 0.299 g (0.8 mmol, 1 eq) Pt(COD)Cl₂ is added (T₂=125° C.). For the final step of the reaction, 0.561 g (1.6 mmol, 2 eq) potassium cycloocta-1,5-diylbis(3-methylpyrazol-1-yl)borate is added. The product is isolated by column chromatography with an eluent mixture matched for polarity. Yield: 151 mg (30%); melting point: 254° C.; molecular formula: C₂₅H₃₂BN₇Pt; molar mass: 636.47 g/mol. 1H NMR in CDCl₃ (600 MHz) δ=7.88 (s, 1H, CHₐᵣₒₘ), 7.64 (s, 2H, CHₐᵣₒₘ), 7.36 (dd, J=7.7, 1.3 HZ, 1H, CHₐᵣₒₘ), 7.33 (dd, J=7.4, 1.3 HZ, 1H, CHₐᵣₒₘ), 7.11 (td, J=7.5, 1.3 Hz, 1H, CHₐᵣₒₘ), 6.97 (td, J=7.4, 1.4 HZ, 1H, CHₐᵣₒₘ), 5.98 (d, J=2.3 Hz, 1H, CHₐᵣₒₘ), 5.97 (d, J=2.3 Hz, 1H, CHₐᵣₒₘ), 3.76-3.71 (m, 1H, CH_{9-BBN}), 3.64 (S, 3H, NCH₃), 2.31 (s, 6H, 2 CCH₃), 2.30-2.19 (m, 2H, CH_{2, 9-BBN}), 2.05-1.84 (m, 4H, CH_{2, 9-BBN}), 1.70-1.45 (m, 6H, CH_{2.9-BBN}), 1.37-1.31 (n, 1H, CH_{9-BBN}). ¹³C NMR in CDCl₃ (151 MHz) δ=161.6 (Cᵢ), 148.6 (Cᵢ), 148.3 (Cᵢ), 145.8 (Cᵢ), 142.0 (CHₐᵣₒₘ), 136.3 (CHₐᵣₒₘ), 135.4 (CHₐᵣₒₘ), 135.0 (CHₐᵣₒₘ), 127.0 (Cᵢ), 125.5 (CHₐᵣₒₘ), 123.8 (CHₐᵣₒₘ), 111.9 (CHₐᵣₒₘ), 104.8 (CHₐᵣₒₘ), 104.5 (CHₐᵣₒₘ), 33.4 (NCH₃), 32.6 (CH_{2, 9-BBN}), 32.4 (CH_{2, 9-BBN}), 31.5 (CH_{2, 9-BBN}), 30.4 (CH_{2, 9-BBN}), 24.7 (CH_{2, 9-BBN}), 24.6 (CH_{2, 9-BBN}), 16.2 (CCH₃), 15.6 (CCH₃). ¹⁹⁵Pt NMR in CDCl₃ (64 MHz) δ=−3806.20 (s). Elemental analysis: calculated C, 47.18%; H, 5.07%; N, 15.40%; found C, 47.09%; H, 4.99%; N, 15.40%.

[Dihydrobis(pyrazol-1-yl-κN²)borate][1-methyl-4-(phenyl-κC²)-1H-1,2,4-triazol-5-ylidene-κC⁵]platinum(II) (3): synthesis analogous to the general synthetic procedure (see Chapter 2,2,1). 230 mg (0.8 mmol, 1 eq.) of 1-methyl-4-phenyl-1H-1,2,4-triazolium iodide and 93 mg (0.4 mmol, 0.5 eq.) of silver(I) oxide are placed in 20 ml DMF. Subsequently, 299 mg (0.8 mmol, 1 eq.) of Pt(COD)Cl₂ is added. For the final step of the reaction, 298 mg (1.6 mmol, 2 eq.) potassium dihydrobis(pyrazol-1-yl)borate (11) is added. The product is isolated by column chromatography with a mixture of eluents adjusted for polarity. Yield: 115 mg (29%); melting point: 179° C.; molecular formula: C₁₅H₁₆BN₇Pt; Molar mass: 500.23 g/mol; 1H-NMR (500 MHz, CDCl₃): δ=8.30 (s, 1H, CH_{Triaz}), 7.71 (dd, J=15.4, 1.5 Hz, 2H, CH_{Pyr}), 7.64 (ddd, J=14.9, 2.3, 0.6 Hz, 2H, CH_{Pyr}), 7.42 (dd, J=7.5, 1.1 Hz, 1H, CH_{Ph}), 7.15 (dtd, J=9.0, 7.7, 1.4 Hz, 2H, CH_{Ph}), 7.07 (td, J=7.3, 1.6 Hz, 1H, CH_{Ph}), 6.26 (dt, J=24.2, 2.2 Hz, 2H, CH_{Pyr}), 3.83 (s, 3H, NCH) ppm. ¹³C-NMR (151 MHz, CDCl₃): δ=159.58 (Cᵢ), 143.96 (C_{i, Ph}), 141.98 (CH_{Pyr}), 141.22 (CH_{Pyr}), 136.36 (CH_{Pyr}), 136.33 (CH_{Pyr}), 136.13 (CH_{Ph}), 135.88 (CH_{Ph}), 128.73 (C_{i,Ph}), 125.89 (CH_{Ph}), 124.31 (CH_{Ph}), 111.07 (CH_{Triaz}), 105.26 (CH_{Pyr}), 105.16 (CH_{Pyr}), 39.70 (NCH₃) ppm. ¹⁹⁵Pt-NMR (129 MHz, CDCl₃): δ=−3787.4 ppm. MS (ESI): m/z=501.1 [M+H]⁺, 1017.4 [2M+NH₄]⁺, 1022.3 [2M+Na]⁺, 1039.2 [2M+K]⁺. Elemental analysis: calculated: C, 36.02%; H, 3.22%; N, 19.60%; found: C, 35.95%; H, 3.09%; N, 19.51%.

[Dihydrobis(4-methylpyrazol-1-yl-κN²)borate][1-methyl-4-(phenyl-κC²)-1H-1,2,4-triazol-5-ylidene-κC⁵]platinum(II) (4): synthesis analogous to the general synthetic procedure (see Chapter 2.2.1). 230 mg (0.8 mmol, 1 eq.) of 1-methyl-4-phenyl-1H-1,2,4-triazolium iodide and 93 mg (0.4 mmol, 0.5 eq.) of silver(I) oxide are placed in 20 ml DMF. Subsequently, 299 mg (0.8 mmol, 1 eq.) of Pt(COD)Cl₂ is added. For the final step of the reaction, 345 mg (1.6 mmol, 2 eq.) potassium dihydrobis(4-methylpyrazol-1-yl)borate is added. The product is isolated by column chromatography with a mixture of eluents matched for polarity. Yield: 113 mg (27%); melting point: 206° C.; molecular formula: C₁₇H₂₀BN₇Pt; Molar mass: 528.28 g/mol; 1H-NMR (500 MHz, CDCl₃): δ=8.28 (s, 1H, CH_{Triaz}), 7.48 (d, J=12.8 Hz, 2H, CH_{Pyr}), 7.44 (dd, J=5.9, 4.8 Hz, 1H, CH_{Ph}), 7.41 (d, J=13.1 Hz, 2H, CH_{Pyr}), 7.17-7.10 (m, 2H, CH_{Ph}), 7.10-7.04 (m, 1H, CH_{Ph}), 3.84 (s, 3H, NCH₃), 2.10 (s, 3H, CCH₃), 2.04 (s, 3H, CCH₃) ppm. ¹³C-NMR (151 MHz, CDCl₃): δ=159.88 (Cᵢ), 143.99 (CH_{Ph}), 141.65 (CH_{Pyr}), 140.80 (CH_{Pyr}), 136.31 (CH_{Ph}), 135.96 (CH_{Ph}), 135.70 (CH_{Pyr}), 135.51 (CH_{Pyr}), 129.07 (C_{i,Ph}), 125.83 (CH_{Ph}), 124.16 (CH_{Ph}), 115.48 (C_{i,Pyr}), 115.33 (C_{i,pyr}), 111.00 (CH_{triaz}), 39.70 (NCH₃), 8.98 (CCH₃), 8.91 (CCH₃) ppm. ¹⁹⁵Pt-NMR (129 MHz, CDCl₃): δ=−3778.6 ppm. MS (ESI): m/z=529.3 [M+H]⁺, 1074.3 [2M+NH₄]⁺, 1079.3 [2M+Na]⁺, 1095.3 [2M+K]⁺. Elemental analysis: calculated: C, 38.65%; H, 3.82%; N, 18.56%; found: C, 38.67%; H, 3.75%; N, 18.51%. [Dihydrobis(3,5-dimethylpyrazol-1-yl-κN²)borate][1-methyl-4-(phenyl-κC²)-1H-1,2,4-triazol-5-ylidene-κC⁵]platinum(II) (5): synthesis analogous to the general synthetic procedure. 230 mg (0.8 mmol, 1 eq.) of 1-methyl-4-phenyl-1H-1,2,4-triazolium iodide and 93 mg (0.4 mmol, 0.5 eq.) of silver(I) oxide are placed in 20 ml DMF. Subsequently, 299 mg (0.8 mmol, 1 eq.) of Pt(COD)Cl₂ is added. For the final step of the reaction, 391 mg (1.6 mmol, 2 eq.) potassium dihydrobis(3,5-dimethylpyrazol-1-yl)borate is added. The product is isolated by column chromatography with an eluent mixture matched for polarity. Yield: 145 mg (33%); melting point: 239° C.; molecular formula: C₁₉H₂₄BN₇Pt; Molar mass: 556.34 g/mol; ¹H-NMR (300 MHz, CDCl₃): δ=8.27 (s, 1H, CH_{Triaz}), 7.30 (dd, J=7.5, 1.0 Hz, 1H, CH_{Ph}), 7.10 (dtd, J=9.0, 7.7, 1.4 Hz, 2H, CH_{Ph}), 6.97 (td, J=7.2, 1.7 Hz, 1H, CH_{Ph}), 5.85-5.74 (m, 2H, CH_{Pyr}), 3.73 (s, 3H, NCH₃), 2.32 (d, J=2.0 Hz, 6H, CCH₃), 2.26 (d, J=2.7 Hz, 6H, CCH₃) ppm. ¹³C-NMR (151 MHz, CDCl₃): δ=160.19 (Cᵢ), 147.62 (CH_{Pyr}), 147.55 (CH_{Pyr}), 145.40 (CH_{Pyr}), 145.00 (CH_{Pyr}), 143.97 (CH_{Ph}), 137.63 (CH_{Ph}), 136.45 (CH_{Ph}), 129.52 (CH_{Ph}), 125.56 (CH_{Ph}), 123.83 (CH_{Ph}), 110.69 (CH_{Triaz}), 105.69 (CH_{Pyr}), 105.19 (CH_{Pyr}), 38.08 (NCH₃), 15.12 (CCH₃), 14.43 (CCH₃), 12.82 (CCH₃), 12.76 (CCH₃) ppm. ¹⁹⁵Pt-NMR (129 MHz, CDCl₃): δ=−3804.8 ppm. MS (ESI): m/z=557.4 [M+H]⁺, 1129.6 [2M+NH₄]⁺, 1134.4 [2M+Na]⁺, 1152.3 [2M+K]⁺. Elemental analysis: calculated: C, 41.02%; H, 4.35%; N, 17.62%; found: C, 41.03%; H, 4.37%; N, 17.69%.

[Cycloocta-1,5-diylbis(pyrazol-1-yl-κN²)borate][1-methyl-4-(phenyl-κC²)-1H-1,2,4-triazol-5-ylidene-κC⁵]platinum(II) (6): synthesis analogous to the general synthetic procedure. 230 mg (0.8 mmol, 1 eq.) of 1-methyl-4-phenyl-1H-1,2,4-triazolium iodide and 93 mg (0.4 mmol, 0.5 eq.) of silver(I) oxide are placed in 20 ml DMF. Subsequently, 299 mg (0.8 mmol, 1 eq.) of Pt(COD)Cl₂ is added. For the final step of the reaction, 471 mg (1.6 mmol, 2 eq.) potassium cycloocta-1,5-diylbis(pyrazol-1-yl)borate is added. The product is isolated by column chromatography with an eluent mixture matched for polarity. Yield: 97 mg (20%); melting point: 294° C.; molecular formula: C₂₃H₂₈BN₇Pt; Molar mass: 608.41 g/mol; 1H-NMR (300 MHz, CDCl₃): δ=8.31 (s, 1H, CH_{Triaz}), 7.81-7.75 (m, 2H, CH_{Pyr}), 7.71 (t, J=2.1 Hz, 2H, CH_{Pyr}), 7.50 (d, J=7.2 Hz, 1H, CH_{Ph}), 7.20-7.02 (m, 3H, CH_{Ph}), 6.22 (dt, J=9.3, 2.0 Hz, 2H, CH_{Pyr}), 3.90 (s, 3H, NCH₃), 3.55 (s, 1H, CH_{9-BBN}), 2.35-2.18 (m, 2H, CH_{9-BBN}), 2.08 1.85 (m, 4H, CH_{9-BBN}), 1.78-1.59 (m, 2H, CH_{9-BBN}), 1.57-1.39 (m, 5H, CH_{2, 9-BBN}& CH_{9-BBN}) ppm. ¹³C-NMR (151 MHz, CDCl₃): δ=160.12 (Cᵢ), 143.78 (CH_{Ph}), 141.43 (CH_{Pyr}), 141.10 (CH_{Pyr}), 136.40 (CH_{Ph}), 135.43 (CH_{Ph}), 134.34 (CH_{Pyr}), 134.15 (CH_{Pyr}), 129.19 (CH_{Ph}), 125.92 (CH_{Ph}), 124.04 (CH_{Ph}), 111.15 (CH_{Triaz}), 105.03 (CH_{Pyr}), 104.69 (CH_{Pyr}), 39.41 (NCH₃), 32.43 (CH_{2-9BBN}), 32.24 (CH_{2-9BBN}), 31.07 (CH_{2-9BBN}), 30.24 (CH_{2-9BBN}), 24.51 (s), 24.46 (CH_{2-9BBN}) ppm. ¹⁹⁵Pt-NMR (129 MHz, CDCl₃): δ=−3692.1 ppm.

MS (ESI): m/z=609.3 [M+H]⁺, 631.3 [M+Na]⁺, 1239.4 [2M+Na]⁺. Elemental analysis: calculated: C, 45.41%; H, 4.64%; N, 16.12%; found: C, 45.05%; H, 4.58%; N, 15.83%.

[Cycloocta-1,5-diylbis(4-methylpyrazol-1-yl-κN²)borate]-[1-methyl-4-(phenyl-κC²)-1H-1,2-triazol-5-ylidene-κC⁵]platinum(II) (7): synthesis analogous to the general synthetic procedure. 230 mg (0.8 mmol, 1 eq.) of 1-methyl-4-phenyl-1H-1,2,4-triazolium iodide and 93 mg (0.4 mmol, 0.5 eq.) of silver(I) oxide are placed in 20 ml DMF. Subsequently, 299 mg (0.8 mmol, 1 eq.) of Pt(COD)Cl₂ is added. For the final step of the reaction, 516 mg (1.6 mmol, 2 eq.) potassium cycloocta-1,5-diylbis(4-methylpyrazol-1-yl)borate is added. The product is isolated by column chromatography with an eluent mixture matched for polarity. Yield: 111 mg (22%); melting point: 302° C.; molecular formula: C₂₅H₃₂BN₇Pt; Molar mass: 636.47 g/mol; 1H-NMR (500 MHz, CDCl₃): δ=8.28 (s, 1H, CH_{Triaz}), 7.54 (d, J=4.1 Hz, 2H, CH_{Pyr}), 7.52 (dd, J=7.5, 1.1 Hz, 1H, CH_{Ph}), 7.47 (d, J=3.1 Hz, 2H, CH_{Pyr}), 7.14 (dtd, J=9.0, 7.7, 1.4 Hz, 2H, CH_{Ph}), 7.07 (td, J=7.3, 1.7 Hz, 1H, CH_{Ph}), 3.91 (s, 3H, NCH₃), 3.47 (s, 1H, CH_{9-BBN}), 2.29-2.19 (m, 2H, CH_{2, 9-BBN}), 2.07 (s, 3H, CCH₃), 2.03 (s, 3H, CCH₃), 2.01-1.83 (m, 4H, CH_{2, 9-BBN}), 1.73-1.57 (m, 2H, CH_{2, 9-BBN}), 1.53-1.41 (m, 4H, CH_{2, 9-BBN}), 1.36 (d, J=1.5 Hz, 1H, CH_{9-BBN}) ppm. ¹³C-NMR (151 MHz, CDCl₃): δ=160.44 (Cᵢ), 143.81 (C_{i,Ph}), 141.09 (CH_{Pyr}), 140.70 (CH_{Pyr}), 136.36 (CH_{Ph}), 135.50 (CH_{Ph}), 133.73 (CH_{Pyr}), 133.54 (CH_{Pyr}), 129.58 (C_{i,Ph}), 125.82 (CH_{Ph}), 123.86 (CH_{Ph}), 115.09 (C_{i,Pyr}), 114.70 (C_{i,Pyr}), 111.07 (CH_{Triaz}), 39.44 (NCH₃), 32.45 (CH_{2-9BBN}), 32.26 (CH_{2-9 BBN}), 31.09 (CH_{2-9 BBN}), 30.28 (CH_{2-9 BBN}), 24.60 (CH_{2- 9 BBN}), 24.55 (CH_{2-9BBN}), 9.12 (CCH₃), 9.08 (CCH₃) ppm. ¹⁹⁵Pt-NMR (129 MHz, CDCl₃): δ=−3683.6 ppm. MS (ESI): m/z=637.4 [M+H]⁺, 1290.5 [2M+NH₄]⁺. Elemental analysis: calculated: C, 47.18%; H, 5.07%; N, 15.40%; found: C, 46.90%; H, 4.86%; N, 15.12%.

[Cycloocta-1,5-diylbis(3-methylpyrazol-1-yl-κN²)borate]-[1-methyl-4-(phenyl-κC²)-1H-1,2,4-triazol-5-ylidene-κC⁵]platinum(II) (8): synthesis analogous to the general synthetic procedure (see Chapter 2,2,1). 230 mg (0.8 mmol, 1 eq.) of 1-methyl-4-phenyl-1H-1,2,4-triazolium iodide and 93 mg (0.4 mmol, 0.5 eq.) of silver(I) oxide are placed in 20 ml DMF. Subsequently, 299 mg (0.8 mmol, 1 eq.) of Pt(COD)Cl₂ is added. For the final step of the reaction, 516 mg (1.6 mmol, 2 eq.) potassium cycloocta-1,5-diylbis(3-methylpyrazol-1-yl)borate is added. The product is isolated by column chromatography with an eluent mixture matched for polarity. Yield: 159 mg (31%); melting point: 275° C.; molecular formula: C₂₅H₃₂BN₇Pt; Molar mass: 636.47 g/mol; 1H-NMR (300 MHz, CDCl₃): δ=8.29 (s, 1H, CH_{Triaz}), 7.64 (t, J=2.1 Hz, 2H, CH_{Pyr}), 7.34 (dd, J=7.5, 1.0 Hz, 1H, CH_{Ph}), 7.12 (dtd, J=9.0, 7.7, 1.4 Hz, 2H, CH_{Ph}), 6.97 (td, J=7.3, 1.6 Hz, 1H, CH_{Ph}), 5.98 (t, J=2.0 Hz, 2H, CH_{Pyr}), 3.79 (s, 3H, NCH₃), 3.75 (d, J=2.3 Hz, 1H, CH_{9-BBN}), 2.32 (s, 3H, CCH₃), 2.28 (s, 3H, CCH₃), 2.25-2.17 (m, 2H, CH_{2, 9-BBN}), 2.03-1.81 (m, 4H, CH_{2, 9-BBN}), 1.72-1.44 (m, 6H, CH_{2, 9-BBN}), 1.34 (d, J=1.5 Hz, 1H, CH_{9-BBN}) ppm. ¹³C-NMR (151 MHz, CDCl₃): δ=160.42 (Cᵢ), 148.41 (CH_{Pyr}), 148.27 (C_{i,Pyr}), 143.76 (C_{i,Ph}), 137.31 (CH_{Ph}), 136.58 (CH_{Ph}), 135.29 (CH_{Pyr}), 134.94 (CH_{Pyr}), 129.68 (C_{i,Ph}), 125.53 (CH_{Ph}), 123.67 (CH_{Ph}), 110.79 (CH_{Triaz}), 104.76 (CH_{Pyr}), 104.49 (CH_{Pyr}), 37.96 (NCH₃), 32.51 (CH_{2.9BBN}), 32.32 (CH_{2.9 BBN}), 31.32 (CH_{2.9BBN}), 30.32 (CH_{2.9BBN}), 24.55 (CH_{2.9BBN}), 24.47 (CH_{2.9BBN}), 15.96 (CCH₃), 15.23 (CCH₃) ppm. ¹⁹⁵Pt-NMR (129 MHz, CDCl₃): δ=−3733.7 ppm. MS (ESI): m/z=637.3 [M+H]⁺, 659.4 [M+Na]⁺, 1295.4 [2M+Na]⁺. MS (ESI): m/z=637.3 [M+H]⁺, 659.4 [M+Na]⁺, 1295.4 [2M+Na]⁺. Elemental analysis: calculated: C, 47.18%; H, 5.07%; N, 15.40%; found: C, 47.04%; H, 4.92%; N, 15.31%.

[Cycloocta-1,5-diylbis(4-methylpyrazol-1-yl-κN²)borate]-[1-methyl-4-(3-methylphenyl-κC²)-1H-1,2,4-triazol-5-ylidene-κC⁵]platinum(II) (9): synthesis analogous to the general synthetic procedure. 243 mg (0.8 mmol, 1 eq.) of 1-methyl-4-(3-methylphenyl)-1H-1,2,4-triazolium iodide and 93 mg (0.4 mmol, 0.5 eq.) of silver(I) oxide are placed in 20 ml DMF. Subsequently, 302 mg (0.8 mmol, 1 eq.) of Pt(COD)Cl₂ is added. For the final step of the reaction, 437 mg (1.36 mmol, 1.7 eq.) potassium cycloocta-1,5-diylbis(4-methylpyrazol-1-yl)borate is added. The product is then isolated by column chromatography with an eluent mixture matched for polarity. Yield: 76 mg (15%); melting point: 293° C.; molecular formula: C₂₆H₃₄BN₇Pt; molar mass: 650.49 g/mol. 1H-NMR (600 MHz, CDCl₃): δ=8.27 (s, 1H, CH_{Triaz}), 7.54 (d, J=6.1 Hz, 2H, CH_{Pyr}), 7.47 (s, 2H, CH_{Pyr}), 7.38 (d, J=7.7 Hz, 1H, CH_{Ph}), 6.99 (s, 1H, CH_{Ph}), 6.92-6.88 (m, 1H, CH_{Ph}), 3.90 (s, 3H, NCH₃), 3.46 (s, 1H, CH_{9-BBN}), 2.34 (s, 3H, CCH_{3,Ph}), 2.28-2.19 (m, 2H, CH_{2, 9-BBN}), 2.07 (s, 3H, CCH_{3,Pyr}), 2.03 (s, 3H, CCH_{3,Pyr}), 2.00 1.83 (m, 4H, CH_{2, 9-BBN}), 1.73-1.57 (m, 2H, CH_{2.9-BBN}), 1.53-1.40 (m, 4H, CH_{2, 9-BBN}), 1.35 (s, 1H, CH_{9-BBN}) ppm. ¹⁹⁵Pt-NMR (129 MHz, CDCl₃): δ=−3688.3 ppm. MS (ESI): m/z=649.0 [M−H]⁺, 651.5 [M+H]⁺, 673.4 [M+Na]⁺, 690.4 [M+K]⁺, 1317.6 [2M+NH₄]⁺, 1323.4 [2M+Na]⁺. Elemental analysis: calculated C, 48.01%; H, 5.27%; N, 15.07%; found C, 48.03%; H, 5.50%; N, 14.76%.

[Cycloocta-1,5-diylbis(3-methylpyrazol-1-yl-κN²)borate]-[1-methyl-4-(3-methylphenyl-κC²)-1/+1,2,4-triazol-5-ylidene-κC⁵]platinum(II) (10): synthesis analogous to the general synthesis procedure II with slight modification of the purification. 243 mg (0.8 mmol, 1 eq.) of 1-methyl-4-(3-methylphenyl)-1H-1,2,4-triazolium iodide and 93 mg (0.4 mmol, 0.5 eq.) of silver(I) oxide are placed in 20 ml DMF. Subsequently, 300 mg (0.8 mmol, 1 eq.) of Pt(COD)Cl₂ is added. For the final step of the reaction, 517 mg (1.6 mmol, 2 eq.) potassium cycloocta-1,5-diylbis(3-methylpyrazol-1-yl)borate is added. The product is then isolated by column chromatography with an eluent mixture matched for polarity. Yield: 125 mg (24%); melting point: 289° C.; molecular formula: C₂₆H₃₄BN₇Pt; molar mass: 650.49 g/mol. ¹H-NMR (600 MHz, CDCl₃): δ=8.27 (s, 1H, CH_{Triaz}), 7.66-7.62 (m, 2H, CH_{Pyr}), 7.21 (d, J=7.6 Hz, 1H, CH_{Ph}), 6.98 (s, 1H, C/A-h), 6.81 (d, J=7.6 Hz, 1H, CH_{Ph}), 5.97 (dd, J=4.0, 2.2 Hz, 2H, CH_{Pyr}), 3.78 (s, 3H, NCH₃), 3.75 (s, 1H, CH_{9-BBN}), 2.32 (S, 3H, CCH_{3,Pyr}), 2.31 (s, 3H, CCH_{3,Pyr}), 2.28 (s, 3H, CCH_{3,Ph}), 2.27-2.20 (m, 2H, CH_{2, 9-BBN}), 2.01-1.83 (m, 4H, CH_{2, 9-BBN}), 1.69 1.46 (m, 6H, CH_{2, 9-BBN}), 1.33 (d, J=1.8 Hz, 1H, CH_{9-BBN}) ppm. ¹⁹⁵Pt-NMR (129 MHz, CDCl₃): δ=−3739.2 ppm. MS (ESI): m/z=649.0 [M−H]⁺, 651.4 [M+H]⁺, 673.4 [M+Na]⁺, 689.4 [M+K]⁺, 1322.5 [2M+Na]⁺; elemental analysis: calculated C, 48.01%; H, 5.27%; N, 15.07%; found: C, 47.74%; H, 5.46%; N, 14.87%.

[Cycloocta-1,5-diylbis(4-methylpyrazol-1-yl-κN²)borate]-[3-methyl-1-(3-methylphenyl-κC²)-1H-imidazolin-2-ylidene-κC²]platinum(II) (11): synthesis analogous to general synthesis procedure II. 240 mg (0.8 mmol, 1 eq.) of 3-methyl-1-phenyl-1H-imidazolium iodide and 94 mg (0.4 mmol, 0.5 eq.) of silver(I) oxide are placed in 20 ml DMF. Subsequently, 299 mg (0.8 mmol, 1 eq.) of Pt(COD)Cl₂ is added. For the final step of the reaction, 516 mg (1.6 mmol, 2 eq.) potassium cycloocta-1,5-diylbis(4-methylpyrazol-1-yl)borate is added. The product is then isolated by column chromatography with a mixture of eluents matched for polarity.

Yield: 132 mg (25%); melting point: 291° C.; molecular formula: C₂₇H₃₅BN₆Pt; molar mass: 649.51 g/mol. 1H-NMR (600 MHz, CDCl₃): δ=7.52 (s, 2H, CH_{Im}), 7.49 (d, J=6.1 Hz, 2H, CH_{Pyr}), 7.34 (d, J=7.6 Hz, 1H, CH_{Pyr}), 7.28 (d, J=2.0 Hz, 1H, CH_{Pyr}), 6.84 (s, 1H, CH_{Ph}), 6.83-6.80 (m, 2H, CH_{Ph}), 3.71 (s, 3H, NCH₃), 3.58 (s, 1H, CH_{9-BBN}), 2.32 (S, 3H, CCH_{3,Ph}), 2.30-2.20 (m, 2H, CH_{2, 9-BBN}), 2.06 (s, 3H, CCH_{3,Pyr}), 2.01 (s, 3H, CCH_{3,Pyr}), 2.00-1.83 (m, 4H, CH_{2, 9-BBN}), 1.73-1.59 (m, 2H, CH_{2, 9-BBN}), 1.54-1.44 (m, 4H, CH_{2, 9-BBN}), 1.35 (s, 1H, CH_{9-BBN}) ppm. ¹³C-NMR (151 MHz, CDCl₃): δ=158.95 (Cᵢ), 147.35 (C_{i,Ph}), 141.17 (CH_{Pyr}), 140.66 (CH_{Pyr}), 134.52 (CH_{Ph}), 133.43 (CH_{Pyr}), 133.20 (CH_{Pyr}), 133.14 (C_{i,Ph}), 125.76 (C_{i,Ph}), 125.15 (CH_{Ph}), 121.01 (CH_{Ph}), 114.85 (CH_{Im}), 114.75 (C_{i,Pyr}), 114.35 (C_{i,Pyr}), 111.53 (CH_{Im}), 37.29 (NCH₃), 32.55 (CH_{2-9 BBN}), 32.32 (CH_{2-9 BBN}), 31.21 (CH_{2-9 BBN}), 30.35 (CH_{2-9 BBN}), 24.68 (CH_{2-9 BBN}), 24.60 (CH_{2-9 BBN}), 21.19 (CCH_{3,Ph}), 9.13 (CCH_{3,Pyr}), 9.09 (CCH_{3,Pyr}) ppm. ¹⁹⁵Pt-NMR (129 MHz, CDCl₃): δ=−3724.6 ppm. MS (ESI): m/z=650.4 [M+H]⁺, 672.4 [M+Na]⁺, 1298.5 [2M+H]⁺, 1316.4 [2M+NH₄]⁺. Elemental analysis: calculated C, 49.93%; H, 5.43%; N, 12.94%; C, 50.05%; H, 5.62%; N, 12.61%.

[Cycloocta-1,5-diylbis(3-methylpyrazol-1-yl-κN²)borate]-[3-methyl-1-(3-methylphenyl-κC²)-1H-imidazolin-2-ylidene-κC²]platinum(II) (12): synthesis analogous to the general synthetic procedure (see Chapter 1). 240 mg (0.8 mmol, 1 eq.) of 3-methyl-1-phenyl-1H-imidazolium iodide and 94 mg (0.4 mmol, 0.5 eq.) of silver(I) oxide are placed in 20 ml DMF. Subsequently, 299 mg (0.8 mmol, 1 eq.) of Pt(COD)Cl₂ is added. For the final step of the reaction, 516 mg (1.6 mmol, 2 eq.) potassium cycloocta-1,5-diylbis(3-methylpyrazol-1-yl)borate is added. The product is isolated by column chromatography with an eluent mixture matched to polarity. After washing and drying, a white, slightly yellowish solid is obtained. Yield: 142 mg (27%); melting point: 260° C.; molecular formula: C₂₇H₃₅BN₆Pt; molar mass: 649.51 g/mol. 1H-NMR (600 MHz, CDCl₃): δ=7.63 (dd, J=8.9, 2.2 Hz, 2H, CH_{Im}), 7.29 (d, J=2.1 Hz, 1H, C_{i,Pyr}), 7.23-7.10 (m, 1H, C_{i,Pyr}), 6.89-6.76 (m, 2H, CH_{Ph}), 6.72 (dd, J=7.5, 0.7 Hz, 1H, CH_{Ph}), 5.95 (dd, J=9.0, 2.1 Hz, 2H, C_{i,Pyr}), 3.89 (s, 1H, CH_{9-BBN}), 3.58 (s, 3H, NCH₃), 2.32 (s, J=5.4 Hz, 3H, CCH_{3,Ph}), 2.30 (s, J=5.2 Hz, 3H, CCH_{3,Pyr}), 2.29 (s, 3H, CCH_{3,Pyr}), 2.28-2.17 (m, 2H, CH_{2,9-BBN}), 2.03-1.83 (n, 4H, CH_{2,9-BBN}), 1.70-1.46 (n, 6H, CH_{2, 9-BBN}), 1.33 (s, 1H, CH_{9-BBN}) ppm. ¹³C-NMR (151 MHz, CDCl₃): δ=158.96 (Cᵢ), 148.40 (C_{i,Pyr}), 148.22 (C_{i,Pyr}), 147.20 (C_{i,Ph}), 136.38 (CH_{Ph}), 134.99 (CH_{Pyr}), 134.63 (CH_{Pyr}), 132.88 (C_{i,Ph}), 125.84 (C_{i,Ph}), 124.89 (CH_{Ph}), 120.81 (CH_{Ph}), 114.98 (CH_{Im}), 111.27 (CH_{Im}), 104.49 (CH_{Pyr}), 104.20 (CH_{Pyr}), 35.65 (NCH₃), 32.61 (CH_{2-9 BBN}), 32.38 (CH_{2-9 BBN}), 31.43 (CH_{2-9 BBN}), 30.38 (CH_{2-9 BBN}), 24.64 (CH_{2-9 BBN}), 24.53 (CH_{2-9 BBN}), 21.24 (CCH_{3,Ph}), 16.01 (CCH_{3,Pyr}), 15.29 (CCH_{3,Pyr}) ppm. ¹⁹⁵Pt-NMR (129 MHz, CDCl₃): δ=−3783.7 ppm. MS (ESI): m/z=650.4 [M+H]⁺, 672.4 [M+Na]⁺, 688.4, [M+K]⁺, 1321.5 [2M+Na]⁺. Elemental analysis: calculated C, 49.93%; H, 5.43%; N, 12.94%; found C, 49.63%; H, 5.34%; N, 12.86%.

Photophysical Characterization and Structures

Emission spectra for compounds A to V are shown in FIGS. 2A to 2E as follows: FIG. 2 A: Emission spectra of compounds A-D, FIG. 2 B: Emission spectra of compounds E-I, FIG. 2 C: Emission spectra of compounds J-M,

FIG. 2 D: Emission spectra of compounds N-Q, and FIG. 2 E: Emission spectra of compounds R-V. The spectra show emission of the respective compound in the visible short-wavelength range and demonstrate the suitability for use in OLEDs. Emission spectra of compounds 3 to 12 are shown in FIGS. 4A to 41. The spectra show the emission of the respective compound in the visible short-wave region and prove the suitability for use in OLEDs. In the emission spectra, the intensity (y-axis) of the emission of the respective compound is plotted against the wavelengths in the visible range (x-axis, wavelengths in nm).

TABLE 2
Photoluminescence data of complexes A to X and 3 to 12, measured at room
temperature in PMMA films each containing 2 wt. % of the respective complex,
and melting or decomposition temperatures of complexes A-X and 3 to 12:

| Complex | λ_{exc} | PLQY | λₑₘ | CIE x | CIE y | Tᵥ | T₀ | mp (º C.) |
|---|---|---|---|---|---|---|---|---|
| A | 370 | 84 | 469 | 0.173 | 0.378 | 15.4 | 18.3 | 239 |
| B | 370 | 92 | 470 | 0.175 | 0.383 | 16.1 | 17.4 | 279 |
| C | 330 | 58 | 468 | 0.159 | 0.198 | 6.2 | 10.7 | 258 |
| D | 330 | 78 | 472 | 0.160 | 0.214 | 6.3 | 8.1 | 269 |
| E | 310 | 42 | 463 | 0.161 | 0.180 | 8.0 | 19.1 | 231 |
| F | 310 | 70 | 461 | 0.159 | 0.175 | 9.1 | 13.1 | 241 |
| G | 310 | 61 | 462 | 0.160 | 0.176 | 8.2 | 13.4 | 248 |
| H | 310 | 69 | 458 | 0.159 | 0.163 | 8.7 | 12.7 | 301 |
| I | 310 | 80 | 458 | 0.158 | 0.156 | 8.7 | 10.9 | 241 |
| J | 310 | 60 | 471 | 0.164 | 0.214 | 9.4 | 15.6 | 270 |
| K | 330 | 44 | 466 | 0.155 | 0.165 | 4.9 | 11.1 | 244 |
| L | 330 | 71 | 465 | 0.155 | 0.172 | 4.9 | 6.9 | 257 |
| M | 330 | 80 | 461 | 0.154 | 0.146 | 5.1 | 6.4 | >310 |
| N | 340 | 79 | 484 | 0.198 | 0.348 | 10.9 | 13.8 | 219 |
| 0 | 340 | 79 | 484 | 0.197 | 0.349 | 10.5 | 13.3 | 264 |
| P | 340 | 80 | 470 | 0.167 | 0.231 | 8.8 | 10.9 | 286 |
| Q | 340 | 79 | 470 | 0.166 | 0.231 | 7.8 | 9.8 | 235 |
| R | 320 | 59 | 449 | 0.154 | 0.112 | 7.7 | 13.0 | 243 |
| S | 320 | 76 | 461 | 0.155 | 0.156 | 9.1 | 11.9 | 227 |
| T | 320 | 77 | 452 | 0.154 | 0.118 | 8.4 | 10.9 | 245 |
| U | 320 | 87 | 449 | 0.154 | 0.109 | 8.5 | 9.8 | 268 |
| V | 320 | 91 | 449 | 0.154 | 0.107 | 8.3 | 9.1 | 283 |
| W | 310 | 69 | 476 | 0.170 | 0.253 | 9.6 | 14.1 | 265 |
| X | 310 | 79 | 457 | 0.159 | 0.160 | 9.6 | 12.2 | 254 |
| 3 | 310 | 13 | 434 | 0.160 | 0.081 | 81.0 | 642.9 | 179 |
| 4 | 310 | 31 | 434 | 0.159 | 0.078 | 7.0 | 22.2 | 206 |
| 5 | 310 | 33 | 435 | 0.155 | 0.069 | 5.8 | 17.8 | 239 |
| 6 | 310 | 46 | 431 | 0.158 | 0.071 | 4.6 | 10.0 | 294 |
| 7 | 310 | 62 | 430 | 0.157 | 0.066 | 8.3 | 13.4 | 302 |
| 8 | 310 | 76 | 431 | 0.156 | 0.067 | 7.7 | 10.2 | 275 |
| 9 | 310 | 82 | 445 | 0.156 | 0.096 | 9.2 | 11.3 | 293 |
| 10 | 310 | 93 | 443 | 0.155 | 0.095 | 9.9 | 10.6 | 289 |
| 11 | 310 | 86 | 458 | 0.156 | 0.138 | 37.9 | 44.3 | 291 |
| 12 | 310 | 92 | 457 | 0.156 | 0.141 | 10.4 | 11.3 | 260 |

λ_{exc} = excitation wavelength;
PLQY = photoluminescence quantum yield
λₑₘ = emission wavelength of highest intensity at room temperature,
CIE x, CIE y = CIE coordinates at room temperature,
Tᵥ = measured phosphorescence lifetime
T₀ = phosphorescence lifetime given as T₀ = 100 Tᵥ/PLQY
mp = melting or decomposition point

The compounds A to X and 3 to 12 according to the invention exhibit clear luminescence in the blue region of the visible spectrum with emission wavelength λem highest intensity at room temperature starting at 430 nm (compound 7) through about 450 (compounds U, V: 449 nm each) and well below 500 nm (compounds N, O: 484 nm each) and thus in the blue region of the spectrum. The melting or decomposition temperatures are almost all located well above 200° C., with peak values above 300° C. with simultaneous highest intensity of the emission wavelength around about 460 nm, thus clearly in the blue region of the spectrum (compounds H, M) or 430 nm (compound 7). At the same time, the complexes according to the invention exhibit comparatively low CIE x and CIE y values. Thus, the CIE x values of the measured compounds are <0.2, in many cases <0.16 (preferred). Further photophysical characteristics of compounds A to V, W, X and 3 to 12 can be taken from Table 2.

FIGS. 3A and 3B show crystal structures of the compounds or complexes A, B, E, F, G, I, J, K, M, N, R, S, T according to the invention. The square-planar arrangement of the ligand atoms coordinating to the central atom is clearly visible in each case.

1. A platinum(II) complex represented by the following formula (I) 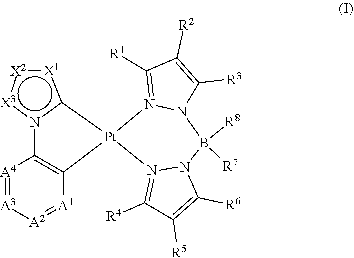
where
(a) A¹ to A⁴ denote: A¹ N or CR^{A1}, A² N or CR^{A2}, A³ N or CR^{A3}, A⁴ N or CR^{A4}, and
(b) X¹ to X³ are:
(i) X¹ NR⁹, X² CR¹⁰, and X³ CR¹¹, or
(ii) X¹ CR¹², X² NR¹³, and X³ CR¹⁴, or
(iii) X¹ NR¹⁵, X² N, and X³ CR¹⁶, or
(iv) X¹ NR¹⁷, X² CR¹⁸, and X³ N, or
(v) X¹ CR¹⁹, X² NR²⁰, and X³ N, or
(vi) X¹ S, X² CR²¹, and X³ CR²², and
(c) R^{A1} to R^{A4} and R¹ to R²² are each independently H, with the proviso that R⁹, R¹³, R¹⁵, R¹⁷, R²⁰ are each not H:
H, halogen atom, donor substituent, acceptor substituent, linear or branched, substituted or non-substituted alkyl radical having 1 to 20 carbon atoms, in which optionally at least one carbon atom is replaced by a heteroatom,
substituted or non-substituted cycloalkyl radical having 3 to 20 carbon atoms, in which optionally at least one carbon atom is replaced by a heteroatom,
substituted or unsubstituted aryl radical having 6 to 30 carbon atoms,
substituted or unsubstituted heteroaryl radical having 5 to 30 carbon and/or hetero atoms, or two or more of the following radicals together with the atoms to which they are bonded form one or more rings and/or one or more fused aromatic ring systems having in each case 5 to 30 carbon and/or hetero atoms, which are in each case substituted or unsubstituted:
R^{A1} to R^{A4} and/or
when X³ is CR¹¹: R⁹ to R¹¹
when X³ is CR¹⁴: R¹² to R¹⁴;
when X³ is CR¹⁶: R¹⁵, R¹⁶;
when X³ is N and X¹ is NR¹⁷: R¹⁷, R¹⁸;
when X³ is N and X¹ is CR¹⁹: R¹⁹, R²⁰; or
when X³ is CR²²: R²¹, R²²;
and/or
two or more of the radicals from the respective radical group R¹ to R³, R⁴ to R⁶ and/or R⁷ and R⁸ form, within the radical group, in each case together with the atoms to which they are bonded, a ring or a fused aromatic ring system having 5 to 30 carbon and/or heteroatoms, the ring or the fused aromatic ring system being substituted or unsubstituted.

2. A platinum(II) complex according to claim 1, wherein R¹ to R⁸ are each: H, a halogen atom, donor substituent, acceptor substituent, linear or branched, substituted or unsubstituted alkyl radical having 1 to 4 carbon atoms, substituted or unsubstituted aryl radical having 6 to 30 carbon atoms, substituted or unsubstituted heteroaryl radical having 5 to 18 carbon and/or hetero atoms, or two or more of the radicals from the respective radical group R¹ to R³, R⁴ to R⁶ and/or R⁷ and R⁸ form, within the radical group, in each case together with the atoms to which they are bonded, a ring or a fused aromatic ring system having 5 to 30 carbon atoms and/or heteroatoms, the ring or the fused aromatic ring system being substituted or unsubstituted.

3. A platinum(II) complex according to claim 1, wherein R^{A1} to R^{A4} as well as R⁹ to R²² are each independently of the other, with the proviso that R⁹, R¹³, R¹⁵, R¹⁷, R²⁰ are each not H: H, a halogen atom, donor substituent, acceptor substituent, linear or branched, substituted or unsubstituted alkyl group having 1 to 9 carbon atoms, in which optionally at least one carbon atom is replaced by a heteroatom, substituted or unsubstituted cycloalkyl group having 3 to 9 carbon atoms, in which optionally at least one carbon atom is replaced by a heteroatom, substituted or unsubstituted aryl group having 6 to 18 carbon atoms, substituted or unsubstituted heteroaryl radical having 5 to 18 carbon and/or hetero atoms, or two or more of the following radicals together with the atoms to which they are bonded form one or more rings and/or one or more fused aromatic ring systems having in each case 5 to 18 carbon and/or hetero atoms, the ring or the fused aromatic ring system being substituted or unsubstituted: R^{A1} to R^{A4} and/or when X³ is CR¹¹: R⁹ to R¹¹; when X³ is CR¹⁴: R¹² to R¹⁴; when X³ is CR¹⁶: R¹⁵, R¹⁶; when X³ is N and X¹ is NR¹⁷: R¹⁷, R¹⁸; when X³ is N and X¹ is CR¹⁹: R¹⁹, R²⁰; or when X³ is CR²²: R²¹, R²².

4. A platinum(II) complex according to claim 1, wherein the respective acceptor substituent and/or donor substituent is each selected from the group consisting of halogen radicals, including —F, —Cl, —Br, —I, alkoxy radicals, carbonyl radicals (—C(O)R), amine radicals (—NH₂, —NHR, —NR₂), amide radicals, CF₃ groups, CN groups, NC groups, SCN groups, the nitro or NO₂ group, bordiorganyl groups —BR₂, where R in each case represents any organic radical.

5. A platinum(II) complex according to claim 1, wherein X¹ to X³ mean: (i) X¹ NR⁹, X² CR¹⁰, and X³ CR¹¹; (ii) X¹ CR¹², X² NR¹³, and X³ CR¹⁴; (iii) X¹ NR¹⁵, X² N, and X³ CR¹⁶; (iv) X¹ NR¹⁷, X² CR¹⁸, and X³ N; or (v) X¹ CR¹⁹, X² NR²⁰, and X³ N.

6. A platinum(II) complex according to claim 1, wherein R^{A1} to R^{A4} are each independently H, a halogen or methyl, donor or acceptor substituent, or R^{A2} and R^{A3} or R^{A3} and R^{A4} together with the atoms to which they are attached form a fused aromatic ring system having 5 to 18 carbon and/or heteroatoms, wherein the fused aromatic ring system is substituted or unsubstituted.

7. A platinum(II) complex according to claim 1, wherein X¹ to X³ are: (i) X¹ NR⁹, X² CR¹⁰, and X³ CR¹¹; (iii) X¹ NR¹⁵, X² N, and X³ CR¹⁶; (iv) X¹ NR¹⁷, X² CR¹⁸, and X³ N; or (v) X¹ CR¹⁹, X² NR²⁰, and X³ N.

8. A platinum(II) complex according to claim 1, wherein X¹ to X³ are: (i) X¹ NR⁹, X² CR¹⁰, and X³ CR¹¹; (iv) X¹ NR¹⁷, X² CR¹⁸, and X³ N; or (v) X¹ CR¹⁹, X² NR²⁰, and X³ N.

9. A process for preparing a platinum(II) complex according to claim 1 comprising contacting platinum compounds suitable therefor, selected from the group consisting of Pt(COD)Cl₂ (COD=cycloocta-1,5-diene), Pt(PPh₃)₂Cl₂, Pt(pyridine)₂Cl₂, Pt(NH₃)₂Cl₂, Pt(acac)₂, PtCl₂, K₂PtCl₄, Pt(COD)Cl₂, with a C\hat{ }C* ligand or a C\hat{ }C* ligand precursor, and the following formula (II), 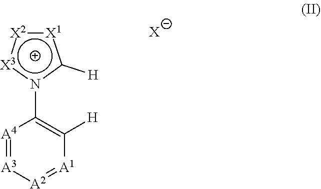
wherein X¹ to X³ and A¹ to A⁴ have the same meanings as described in claim 1, and X⁻ denotes an anion, such as a halide ion, or an anion selected from the group consisting of BF₄⁻, PF₆⁻, N(SO₂CF₃)₂⁻, SbF₆⁻, ClO₄⁻, ½ SO₄²⁻, and a bis(pyrazolyl)borate ligand.

10. Use of a platinum(II) complex according to claim 1 in an OLED.
